(19) United States
(12) Patent Application Publication
(10) Pub. No.: US 2007/0218646 A1
(43) Pub. Date: Sep. 20, 2007

(54) PROCESS FOR PRODUCING ELECTRIC CONDUCTOR

(75) Inventors: Taro Hitosugi, Kawasaki-shi (JP); Atsuki Ueda, Kawasaki-shi (JP); Naoomi Yamada, Kawasaki-shi (JP); Tetsuya Hasegawa, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: Asahi Glass Company, Limited, Chiyoda-ku (JP); Kanagawa Academy of Science and Technology, Kawasaki-shi (JP)

(21) Appl. No.: 11/688,013

(22) Filed: Mar. 19, 2007

(30) Foreign Application Priority Data
Mar. 20, 2006 (JP) 2006-077689
Aug. 28, 2006 (JP) 2006-230821

(51) Int. Cl. H01L 21/76

(52) U.S. Cl. 438/449; 438/491

(57) ABSTRACT

An electric conductor is provided, which is excellent in electric conductivity and has good transparency.

A process for producing electric conductor comprising a step of forming on a surface of a substrate body 11 a precursor layer 12′ made of titanium oxide doped with one or at least two dopants selected from the group consisting of Nb, Ta, Mo, As, Sb, Al, Hf, Si, Ge, Zr, W, Co, Fe, Cr, Sn, Ni, V, Mn, Tc, Re, P and Bi; and a step of annealing the precursor layer 12′ in a reducing atmosphere to form a metal oxide layer 12.

### BACKGROUND OF THE INVENTION

1. Field of the Invention

The present invention relates to a process for producing an electric conductor.

2. Discussion of Background

In recent years, large-sized liquid crystal display panels and small-sized liquid crystal display panels for portable devices are increasingly demanded. In order to realize these, low power consumption of display elements is required, and application of transparent electrodes having high visual-light transmittance and low resistance, are essential.

In particular, organic electroluminescence elements that are being developed recently, are self-emission type elements effectively applicable to small-sized portable devices, but they have a problem that they consume large power since they use a current-drive method. Further, plasma display panels (PDP) being widely spread in the market and field emission displays (FED) being developed as the next generation display, each has a problem that they have a structure of high power consumption. From these reasons, low-resistance transparent conductive thin films are highly expected.

As a typical example of transparent conductive thin film is an indium tin oxide film (hereinafter referred to as ITO film) made of indium oxide doped with tin. An ITO film is excellent in transparency and has high conductivity, but it has a demerit that since the earth crust contains only 50 ppb of In, the raw material cost increases as In resource is exhausted.

In recent years, as a material of transparent electric conductor, titanium dioxide (TiO₂) having both chemical resistance and durability is attentioned (for example Non-Patent Document 1).

Non-Patent Document 1 proposes a method of obtaining a transparent conductor by forming on a substrate a metal oxide layer of M:TiO₂ (M is e.g. Nb or Ta) having an anatase type crystal structure. This document shows that a single crystal thin film (solid solution) of M:TiO₂ having an anatase type crystal structure formed by epitaxial growth, significantly increases electric conductivity while it maintains transparency.

The following Patent Document 2 proposes a method of obtaining a layered structure of transparent conductive thin film by forming on a transparent substrate body a layered structure in which a transparent high-refractive-index thin film layer containing hydrogen and a metal thin film layer are alternately layered. The transparent high-refractive-index thin film layer is made of e.g. titanium oxide.

None of these documents does not describe annealing after the forming of the metal oxide layer.

Non-Patent Document 1): Oyo Butsuri (Applied Physics) Vol. 73, No. 5 (2004), p. 587-592

Patent Document 1): WO2006/016608

Patent Document 2): JP-A-2004-95240

The single crystal thin film of M:TiO₂ having an anatase type liquid crystal structure described in Patent Document 1, is difficult to produce and its productivity is low, and thus, it is not likely that the film is practically used.

The transparent refractive index thin film layer of Patent Document 2 tends to have insufficient transparency since it contains hydrogen at a time of forming the film.

Thus, it has been difficult to realize an electric conductor having low electric resistance and is excellent in transparency.

### SUMMARY OF THE INVENTION

The present invention has been made considering the above-mentioned circumstances, and it is an object of the present invention to provide a process for producing a titanium oxide type electric conductor excellent in electric conductivity and having good transparency with high productivity.

In order to solve the above-mentioned problems, the process for producing an electric conductor of the present invention comprises a step of forming on a surface of a substrate body a precursor layer made of titanium oxide doped with one or at least two dopants selected from the group consisting of Nb, Ta, Mo, As, Sb, Al, Hf, Si, Ge, Zr, W, Co, Fe, Cr, Sn, Ni, V, Mn, Tc, Re, P and Bi, and a step of annealing the precursor layer in a reducing atmosphere to form a metal oxide layer.

According to the present invention, it is possible to produce a titanium oxide type electric conductor excellent in conductivity and having good transparency with high productivity.

### BRIEF DESCRIPTION OF THE DRAWINGS

FIG. 1: A view showing the state that a metal oxide layer is formed on a substrate.

FIG. 2: A view showing the construction of a PLD apparatus.

FIG. 3: A view comparing a metal oxide layer according to the present invention with an anatase type epitaxial film.

FIG. 4A: A view showing the carrier hole density in a metal oxide layer according to the present invention in comparison with that in an anatase type epitaxial film.

FIG. 4B: A view showing the hole mobility in a metal oxide layer according to the present invention in comparison with that in an anatase type epitaxial film.

FIG. 5: Views showing (a) the transmittance T, the reflectivity R and (b) the absorptivity of the metal oxide layer according to the present invention.

FIG. 6: Views showing (a) the transmittance T, the reflectivity R and (b) the absorptivity of the metal oxide layer according to the present invention.

FIG. 7: A view showing the transmittance T and the reflectivity R of the metal oxide layer according to the present invention.

FIG. 8: A SEM picture of the metal oxide layer according to the present invention.

FIG. 9A: A view showing a comparison of measurement results (XRD profiles) by X-ray diffraction before and after annealing in a H₂ atmosphere.

FIG. 9B: A view showing a comparison of measurement results (XRD profiles) by X-ray diffraction before and after annealing in a H₂ atmosphere.

FIG. 9C: A view showing a comparison of measurement results (XRD profiles) by X-ray diffraction before and after annealing in a H₂ atmosphere.

FIG. 9D: A view showing a comparison of measurement results (XRD profiles) by X-ray diffraction before and after annealing in a H₂ atmosphere.

FIG. 10: A view showing the state spectrum of the metal oxide layer according to the present invention measured by an X-ray photoelectron spectrum analyzer.

FIG. 11A: AFM (atomic force microscope) data of a metal oxide layer according to the present invention.

FIG. 11B: AFM (atomic force microscope) data of a metal oxide layer according to the present invention.

FIG. 12: A view showing change of resistivity before and after annealing.

FIG. 13: A view showing temperature dependence of resistivity.

FIG. 14: Views showing temperature dependence of carrier density and temperature dependence of hole mobility.

FIG. 15: A view showing a comparison of measurement results (XRD profiles) by X-ray diffraction before and after annealing in a H₂ atmosphere.

FIG. 16: A cross-sectional TEM picture of a Nb-doped TiO₂ thin film that is formed at 250° C. and annealed.

FIG. 17: A cross-sectional TEM picture of a Nb-doped TiO₂ thin film that is formed at 250° C. and annealed.

FIG. 18: A electron beam diffraction image of a Nb-doped TiO₂ thin film formed at 250° C. and annealed.

FIG. 19: A cross-sectional TEM image of a Nb-doped TiO₂ thin film formed at a room temperature and before annealing (as grown).

FIG. 20: A cross-sectional TEM image of a Nb-doped TiO₂ thin film formed at a room temperature and annealed.

FIG. 21: A cross-sectional TEM image of a Nb-doped TiO₂ thin film formed at a room temperature and annealed.

FIG. 22: A cross-sectional TEM image of a Nb-doped TiO₂ thin film observed at a magnification of 5×10⁵X that was observed at 2.5×10⁶X.

FIG. 23: A view showing the relation between resistance change and annealing time.

FIG. 24: A view showing the relation between XRD and annealing time.

FIG. 25: A view showing the influence of temperature-rising time at a time of annealing on crystallinity.

FIG. 26: A view showing XRD before and after annealing in a case of non-doped TiO₂.

FIG. 27: A view showing the relation between annealing temperature and resistivity.

FIG. 28: A view showing the relation between annealing temperature and resistivity in an anatase type epitaxial film.

FIG. 29: A view showing a comparison of measurement results (XRD profiles) by X-ray diffraction of a TiO₂ thin film doped with 6 atomic % of Nb formed on a thermally oxidated Si substrate, before and after annealing in a H₂ atmosphere.

FIG. 30: Views showing XRD data of a composition spread thin film formed on a thermally oxidated Si and having a Nb concentration gradient of from 0 at % to 20 at %.

FIG. 31: A view showing the resistance of a composition spread thin film formed on a thermally oxidated Si and having a Nb concentration gradient of from 0 at % to 20 at %.

FIG. 32: A view showing a measurement sample for calculating resistance.

FIG. 33: Views showing a comparison of measurement results (XRD patterns) by an X-ray diffraction at different oxygen concentrations.

FIG. 34: Views showing the dependency of XRD pattern on film-forming parameters.

FIG. 35: A view showing a comparison between a Nb:TiO₂ film and a TiO₂ film in XRD pattern.

FIG. 36: A view showing a comparison between a Nb:TiO₂ film and a TiO₂ film in resistivity.

FIG. 37: Views showing dependence of carrier-transportation properties on film-forming parameters.

FIG. 38: a view showing the relation between film-forming speed and O₂/(Ar+O₂) ratio.

FIG. 39: A view showing spectral transmission characteristic of a Nb:TiO₂ film.

FIG. 40: A view showing temperature-dependence of electrical characteristics of a Nb:TiO₂ film.

FIG. 41: Views showing orientation characteristics in relation to a target-substrate distance in a chamber in a sputtering apparatus.

FIG. 42: Views each showing increase of mobility according to orientation change.

### EXPLANATION OF NUMERALS

11: substrate

12: metal oxide layer

12′: precursor layer

30: PLD apparatus

31: chamber

32: light-emitting device

33: reflective mirror

34: lens

36: IR lamp

39: target

40: oil rotary pump

41: check valve

42: turbo molecular pump

43: pressure valve

45: oxygen gas flow rate adjusting valve

### DETAILED DESCRIPTION OF THE PREFERRED EMBODIMENTS

From now, embodiments of the present invention are described in detail.

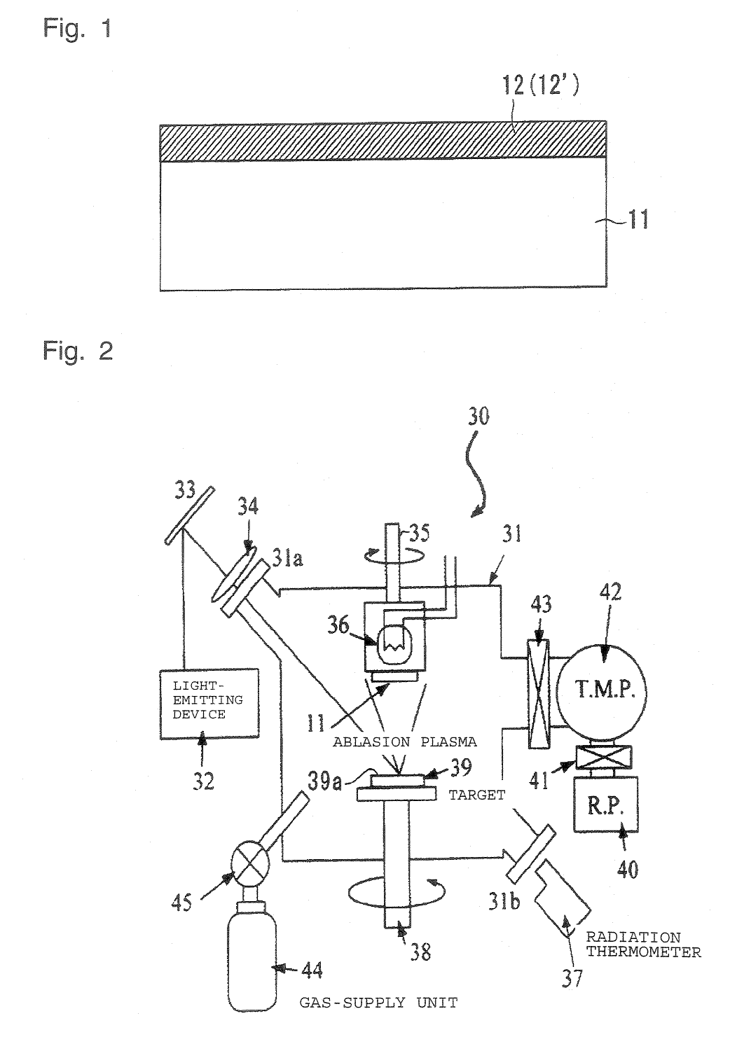

FIG. 1 is a cross-sectional view showing an embodiment of the present invention. In this embodiment, first of all, on a surface of a substrate (substrate body) 11, a precursor layer 12′ made of titanium oxide doped with a predetermined dopant is formed, and the precursor layer 12′ is annealed in a reducing atmosphere to obtain an electric conductive layer (electric conductor) 12 made of a metal oxide. The electric conductive layer 12 is made of titanium oxide containing a predetermined dopant, and hereinafter, it may be referred to as metal oxide layer 12.

Substrate Body

The material of substrate body is not particularly limited. It may, for example, be a single crystal material, a polycrystal material, an amorphous material, or a material as a mixture of these crystal states.

Specific examples of the material include a substrate made of single crystal or polycrystal strontium titanate (SrTiO₃); a single crystal substrate or a polycrystal substrate made of a rock salt type crystal of perovskite type crystal structure or a similar structure; a quartz substrate; a glass substrate of e.g. a non-alkali glass (for example, model name: AN100; manufactured by Asahi Glass Company, Limited); a plastic substrate; and a semiconductor substrate such as a silicon substrate (thermally oxidized Si substrate) on a surface of which a thermally oxidized film is formed. These materials may contain a dopant or an impurity within a range not diminishing effects of the present invention.

In a case of employing a single crystal substrate of SrTiO₃ as the substrate 11, the substrate is preferably one finished so that the substrate surface corresponds to the (100) surface.

In the present invention, even in a case of substrate body a part of whose surface is amorphous, a good electrically conductive film can be formed on a surface of the substrate body. In the present invention, crystal state of a substrate body is preferably polycrystal, amorphous or a state in which polycrystal and amorphous are mixed.

The shape of the substrate body of the present invention is not particularly limited. For example, the substrate body may be a plate-shaped substrate 11 or a film shape such as a plastic film.

The thickness of the substrate 11 is not particularly limited. In a case where the transparency is of the substrate 11 is required, the thickness is preferably at most 1 mm. In a case of a plate-shaped substrate where a mechanical strength is required and the transmittance may be sacrificed to a certain extent, the thickness may be more than 1 mm. The thickness of the substrate 11 is preferably, for example, from 0.2 to 1 mm.

As the substrate 11, a polished substrate may be employed as the case requires. A substrate having crystallinity such as a SrTiO₃ substrate, is preferably polished for use. For example, such a substrate is mechanically polished by using a diamond slurry as an abrasive. In such a mechanical polishing, it is preferred to gradually reduce the grain size of the diamond slurry to be used, and to carry out mirror polishing with a diamond slurry having a grain size of about 0.5 μm in the final step. Thereafter, a further polishing with a colloidal silica may be carried out to obtain a surface roughness of 10 Å (1 nm) or less in terms of root mean square (rms) roughness.

Before forming the precursor layer 12′, the substrate 11 may be preliminarily processed. This preliminary process may, for example, be carried out in the following steps. First of all, the substrate is cleaned with e.g. acetone or ethanol. Then, the substrate is immersed in a high-purity hydrochloric acid (for example, EL grade, concentration is 36 mass %, manufactured by Kanto Chemical Co., Ltd.) for 2 minutes. Then, substrate is moved into a purified water to wash out e.g. the hydrochloric acid. Then, the substrate is moved into a new purified water and subjected to an ultrasonic cleaning for 5 minutes. Subsequently, the substrate is taken out from the purified water, and nitrogen gas is blown against the substrate surfaces to remove water from the substrate surfaces. These treatments are carried out at, for example, a room temperature. By these treatments, e.g. oxides and organic substances are considered to be removed from the substrate surfaces. In the above example, hydrochloric acid is used, but instead of this, an acid such as nitrohydrochloric acid or hydrofluoric acid may be used. The treatment with the acid may be carried out at a room temperature or a heated acid may be used.

Precursor Layer

The precursor layer 12′ is made of titanium oxide doped with one or at least two dopants selected from the group consisting of Nb, Ta, Mo, As, Sb, Al, Hf, Si, Ge, Zr, W, Co, Fe, Cr, Sn, Ni, V, Mn, Tc, Re, P and Bi. The titanium oxide of the present invention is one in which Ti sites are substituted by metal atoms M (dopant), and hereinafter it may be referred to as “M:TiO₂”. In the precursor layer 12′, content of impurities other than the dopant metal atoms (M), oxygen atoms (O) and titanium atoms (Ti) is preferably at most 0.1 atomic %.

Particularly, when Nb, Ta, Mo, As, Sb, Al, Hf, Si, Ge, Zr or W is employed as a dopant, improvement of electric conductivity is expected while transparency of the metal oxide layer 12 is maintained. Further, when Co, Fe, Cr, Sn, Ni, V, Mn, Tc, Re, P or Bi is employed as a dopant, magneto-optics effects or ferromagnetism is expected.

Among the above-mentioned dopants, it is preferred to employ Nb, Ta, Mo, As, Sb or W, and particularly, it is preferred to employ Nb and/or Ta in terms of improving electric conductivity.

The content of dopants in the precursor layer 12′ is maintained even after annealing. Accordingly, the content of dopants in the precursor layer 12′ is set to be the same as a desired content of dopants in the metal oxide layer 12 after the annealing.

Provided that the total amount of titanium atoms (Ti) and dopant metal atoms (M) is 100 atomic % (this definition is applied hereinafter), the content of dopants in the metal oxide layer 12 is preferably more than 0 atomic % and at most 50 atomic %. If the content is more than 50 atomic %, in the metal oxide layer 12 after annealing, the characteristic of TiO₂ as a matrix material becomes weak. More preferably, the content is at most 20 atomic %, particularly preferably at most 10 atomic %. On the other hand, in order to satisfactory obtain high transparency and low resistance of the metal oxide layer 12 after annealing, the content of dopants in the precursor layer 12′ is more preferably at least 1 atomic %.

Further, it is possible to adjust light-transmittance characteristics of the metal oxide layer 12 by the content of dopants. For example, by increasing Nb doping amount, it is possible to cut a red region of longer wavelength so that the metal oxide layer 12 only transmits blue light.

Crystal state of the precursor layer 12′ affects crystal state of the metal oxide layer 12 after annealing. Accordingly, the crystal state of the precursor layer 12′ is set so that a desired crystal state is obtained after annealing.

The crystal state of the metal oxide layer 12 after annealing, is preferably amorphous state, polycrystal state or a state in which amorphous and polycrystal are mixed. However, for the reason of easiness of obtaining low resistance, the polycrystal state or the state in which amorphous and polycrystal are mixed, is more preferred. Further, for the reason of easiness of production, a state that the metal oxide layer 12 is partially amorphous, namely, a state in which amorphous and polycrystal are mixed, is preferred. When polycrystal is present in the metal oxide layer 12, crystals constituting the polycrystal are preferably crystals of anatase type for the reason of easiness of obtaining low resistance.

Further, since an amorphous structure usually does not produce birefringence, an amorphous state or a state in which amorphous and polycrystal are mixed, is preferred in terms of optical characteristic.

If the crystal state of the precursor layer 12′ is amorphous, crystal state after annealing becomes amorphous state or a mixed state of amorphous and polycrystal depending on annealing conditions. If the annealing temperature is higher than the crystallization temperature, polycrystal is formed.

If the crystal state of the precursor layer 12′ is a mixed state of amorphous and polycrystal, the crystal state after annealing becomes a mixed state of amorphous and polycrystal. Further, under specific conditions, it is possible to obtain a complete polycrystal.

When polycrystal is present in the precursor layer 12′, if crystals constituting the polycrystal are of anatase type, the polycrystal of the metal oxide layer 12 after annealing becomes that of anatase type. If the polycrystal in the precursor layer 12′ is that of rutile type, the polycrystal in the metal oxide layer 12 becomes that of rutile type.

The thickness of the precursor layer 12′ may decrease by from 0 to about 10% by annealing. Accordingly, the thickness of the precursor layer 12′ is preferably set according to production conditions so that the thickness of the metal oxide layer 12 after annealing is becomes a desired thickness.

The thickness of the metal oxide layer 12 is not particularly limited, and it can be appropriately set according to e.g. its application. For example, the thickness is preferably from 20 to 1,000 nm, more preferably from 100 to 200 nm.

Process for Forming Precursor Layer

The precursor layer can be formed by appropriately using a known film-forming method. Specifically, a physical vapor deposition (PVD) method such as a pulsed laser deposition (PLD) method or a sputtering method; a chemical vapor deposition (CVD) method such a MOCVD method; or a film-forming method by using a synthesizing process from a solution such as a sol gel method or a chemical solution method.

Particularly, a PLD method is preferred since it produces good film conditions, and a sputtering method is preferred since it provides easiness of film-forming regardless of crystallinity of a substrate.

PLD Method

Now, as a first example, a method of forming the precursor layer 12′ on the substrate 11 by a PLD method is described.

FIG. 2 is a schematic construction view showing an example of a PLD apparatus 30 suitably employed for this method. The PLD apparatus 30 has a construction that in a chamber 31, a substrate 11 and a target 39 are disposed so that their opposing surfaces become substantially parallel with each other. The chamber 31 is configured to maintain appropriate vacuum pressure and prevent interfusion of external impurities to produce high quality thin film.

The substrate 11 is held so as to be rotational around an rotational axis 35 perpendicular to the surface of the substrate 11 by a motor not shown. Further, the target 39 is held so as to be rotational around a rotational axis 38 perpendicular to the surface 39a by a motor not shown.

In the chamber 31, an IR lamp 36 is disposed for heating the substrate 31. The temperature of the substrate 11 is monitored by a radiation thermometer 37 disposed outside the chamber 31 through a window 31b, and the temperature is always controlled to be constant.

Outside the chamber 31, a gas supply unit 44 is disposed for injecting oxygen gas into the chamber 31 via an oxygen gas flow-rate-adjusting valve 45 for adjusting flow rate of the oxygen gas. Further, in order to achieve film-forming under a reduced pressure, a turbo molecular pump 42 and a pressure valve 43 are connected to the chamber 31. The pressure in the chamber 31 is controlled by using the oxygen gas flow-rate-adjusting valve 45 and the pressure valve 43 so that the oxygen partial pressure becomes from 1×10⁻⁵ to 1×10⁻⁴ Torr (1.33×10⁻³ Pa to 1.33×10⁻² Pa) Here, to the turbo molecular pump 42, an oil rotary pump 40 and a check valve 41 are connected, whereby the pressure in the exhaust side of the turbo molecular pump 42 is always maintained to be 10⁻³ Torr (1.33×10⁻¹ Pa) or lower.

Outside of the chamber 31, a light-emitting device 32 is provided so that pulsed laser light emitted from the light-emitting device 32 is, via a reflective mirror 33 for adjusting radiation position, a lens 34 for controlling a spot size, and a window 31a of the chamber 31, incident into a surface 39a of the target 39 opposed to the substrate 11. The light-emitting device 32 emits as the pulsed laser light, KrF excimer laser light having a pulse frequency of 1 to 10 Hz, a laser fluence (laser power) of 1 to 2 J/cm² and a wavelength of 248 nm. The emitted pulsed laser light is adjusted by the reflective mirror 33 and the lens 34 so that its focal point is in the vicinity of the target 39, and the light is incident at an angle of about 45° to the surface 39a of the target 39.

The target 39 is, for example, made of a Nb:TiO₂ sintered product containing 6 atomic % of Nb. This Nb:TiO₂ is an example whose dopant (M) is Nb. The dopant (M) may be any one of the above-mentioned dopants of the present invention, and a plurality of metals may be employed in combination.

For example, a Nb:TiO₂ sintered product can be produced by mixing powders of TiO₂ and Nb₂O₅ weighed so as to be desired atomic ratio, and heating and molding the mixed powders. Here, the composition of the target is approximately the same as the composition of the film.

In order to form the precursor layer 12′ by using the PLD apparatus 30, first of all, the substrate 11 is disposed in the chamber 31. Then, in order to remove impurities on the surface of the substrate and to obtain a flat surface of atomic level, a preliminarily annealing may be carried out under the conditions that the oxygen partial pressure is 10⁻⁵ Torr (1.33×10⁻³ Pa) and the substrate temperature is 500° C. The preliminary annealing is preferably carried out, for example, at least 1 hour.

Then, maintaining the oxygen partial pressure in the chamber to be about 1×10⁻⁵ to 1×10⁻⁴ Torr (1.33×10⁻³ Pa to 1.33×10⁻² Pa), the substrate temperature is set to be a predetermined temperature and the substrate 11 is rotated. Further, while the target 39 is rotated, the target 39 is irradiated with the above-mentioned pulsed laser light intermittently to rapidly raise the temperature of the surface of the target 39 to produce abrasion plasma. Ti atoms, Nb atoms and O atoms contained in the abrasion plasma gradually change their state as they repeatedly collide and react with oxygen gas in the chamber 31 and move to the substrate 11. Particles containing Ti atoms, Nb atoms and O atoms reached the substrate 11, are, as they are, diffused into the surface of the substrate 11 to form a thin film. Thus, a precursor layer 12′ is formed on the substrate 11.

Sputtering Method

Now, as the second example, a method of forming the precursor layer 12′ on the substrate 11 by a sputtering method, is described.

As a sputtering apparatus, a known apparatus can be appropriately used. For example, a reactive DC magnetron sputtering apparatus can be used.

First of all, in a vacuum chamber of the sputtering apparatus, a target and a substrate 11 are set. The substrate 11 is set so as to oppose to the surface of the target. A magnet is disposed on the back side of the target. As the target, for example, a titanium alloy containing a predetermined dopant such as a Ti—Nb alloy containing 6 atomic % of Nb, may be employed. Or else, a metal oxide such as a Nb:TiO₂ sintered product may also employed as the target. The dopant may be any one of the above-mentioned dopants of the present invention, and a plurality of metal types may be used in combination. Here, the content of the dopant in the target becomes substantially the same as the content of the dopant in the film.

The content of the dopant in the target is preferably more than 0 atomic % and at most 50 atomic % provided that the total amount of titanium atoms (Ti) and dopant metal atoms (M) is 100 atomic %. If the content exceeds 50 atomic %, the characteristics of TiO₂ as the matrix becomes weak in a metal oxide layer 12 after annealing. The content is preferably at most 20 atomic %, particularly preferably at most 10 atomic %. Further, in order to satisfactorily obtain high transparency and low resistance of the metal oxide layer 12 after annealing, the content of the dopant in the target is preferably at most 1 atomic %.

Subsequently, inside of the vacuum chamber is evacuated to be 5×10⁻⁴ Pa or lower, O₂ gas and an inert gas are introduced as sputtering gases and the pressure is adjusted to be a predetermined sputtering pressure. The sputtering pressure is preferably from 0.1 to 5.0 Pa. As the inert gas, one type or at least two types selected from the group consisting of Ar, He, Ne, Kr and Xe, may be used. It is preferred to adjust the introduction amounts so that the ratio (volume ratio) of O₂/(inert gas+O₂) in the sputtering gas becomes 0.001 to 30 vol %.

Subsequently, while the sputtering pressure is maintained, a magnetic field of predetermined intensity is generated by the magnet on the back side of the target and a predetermined voltage is applied to the target to form the precursor layer 12′ on the substrate.

Substrate Temperature at the Time of Film-Forming

In each of the film-forming methods, if the substrate temperature at a time of forming the precursor layer 12′ on the substrate 11 is too high, rutile type crystals are formed in the precursor layer, such being not preferred. Accordingly, the upper limit of the substrate temperature is preferably at most 600° C., and it is preferably at a room temperature or lower to obtain a metal oxide layer of lower resistance. If the film-forming is carried out at a room temperature or lower, the precursor layer 12′ becomes amorphous state. The lower limit of the substrate temperature is not particularly limited so long as it is a temperature at which the film-forming is possible. The lower limit is, for example, at least 77 K (about −196° C.).

Here, a “room temperature” in terms of the substrate temperature at the time of film-forming, means a possible temperature range of the substrate at the time of film-forming without heating the substrate. It is from about 25 to 100° C. in a PLD method, and about from 25 to 80° C. in a sputtering method. In order to lower the resistance of the metal oxide layer 12, it is preferred to cool the substrate so that the substrate temperature at the time of film forming is maintained to be, for example, about from 25 to 50° C. as the case requires.

Annealing

In the present invention, the precursor layer 12′ is annealed (hereinafter it may also be referred to as post annealing) in a reducing atmosphere to form a metal oxide layer 12 as an electric conductor.

The reducing atmosphere in the present invention means an atmosphere in which the partial pressure of an oxidation gas is at most 1.2×10⁻⁵ Pa. The oxidation gas means a gas capable of providing oxygen to the precursor layer 12′ in the annealing step, and the gas may specifically be e.g. O₂, O₃, NO, NO₂ or H₂O. In a case where at least two types of oxidation gases are contained in the atmosphere, it is necessary that the total of their partial pressures is within the above-mentioned range. The partial pressure of oxidation gases in the reducing gas atmosphere is preferably at most 1×10⁴ Pa, more preferably at most 10 Pa, the most preferably about 1×10⁻⁸ Pa. As the partial pressure of oxidation gas is smaller, a metal oxide layer 12 of lower resistance can be obtained.

Further, in order to make the metal oxide layer 12 have lower resistance, the reducing atmosphere preferably contains H₂ and/or CO, more preferably contains H₂ in plasma state.

Accordingly, it is preferred to evacuate the annealing atmosphere once and subsequently introduce hydrogen (H₂) to carry out annealing. The evacuation state is preferably such that the pressure of the atmosphere is, for example, within the range of from 10³ to 10⁻⁸ Pa.

Annealing in the present invention means an operation of raising the temperature of the precursor layer 12′ to a predetermined temperature (annealing temperature) and subsequently lowering the temperature. In such a case as this embodiment where the precursor layer 12′ is formed on the substrate 11, it is possible to make the substrate temperature to be the annealing temperature.

The annealing temperature is preferably a temperature higher than a crystallization temperature of the precursor layer 12′. For example, the crystallization temperature of TiO₂ doped with no dopant is about 400° C., and the crystallization temperature tends to be lower as the material is doped with dopant. Accordingly, preferred annealing temperature to satisfactorily lower the resistance of the metal oxide layer 12, depends on the type of the dopant and is preferably at least 300° C. If the annealing temperature is too high, anatase type crystal structures may be destroyed in the annealing step, and thus, the annealing temperature is preferably at most 900° C. In terms of heat resistance of the substrate 11, reduction of energy and reduction of temperature-rising time etc., the annealing temperature is preferably lower. The preferred range of annealing temperature is 350 to 850° C., more preferably 350 to 800° C.

A time (annealing time) of maintaining the predetermined annealing temperature, is not particularly limited. The annealing time may be any length so long as desired characteristics can be obtained after annealing, and the annealing time can be set within a range of, for example, from 1 to 120 min. The annealing time is, for example, preferably 1 to 60 min. depending on other conditions.

A metal oxide layer 12 thus obtained has a good electric conductivity. Generally, an electric conductor means, for example, a material having a resistivity of 10⁰ Ωcm or lower at a room temperature. If the resistivity at a room temperature is 10⁻³ Ωcm or lower, application of the metal oxide layer expands, such being preferred. Further, transparency of the metal oxide layer becomes good and a good transmittance is obtained particularly in the visual light region. For example, it is possible to realize a transparent electric conductor having a transmittance of at least 80% in the visible light region and having a resistivity of at most 2×10⁻⁴ Ωcm. Accordingly, such an electric conductor is suitable as an electric conductor for which transparency is required.

Further, at a time of forming the single crystal thin film of M:TiO₂ having an anatase type crystal structure by an epitaxial method described in Patent Document 1, alignment of crystals in a substrate is important and strict control of production conditions is required. On the other hand, according to the production process of the present invention, an electric conductor can be formed not only on a glass substrate but also on a plastic surface or a silicon substrate such as an amorphous silicon substrate, and thus, wider range of substrate selection is possible and production becomes easy. Accordingly, application of the electric conductor is wide.

Particularly, as shown in Examples to be described later, by forming a precursor layer by a PLD method and annealing it in H₂ or in a vacuum, a metal oxide layer close to amorphous state containing polycrystals can be formed on a glass substrate, and it has been confirmed that the metal oxide layer shows transparent electric conductivity. It has been unpredictable that such a metal oxide shows transparent electric conductivity. Further, it has also become clear that by carrying out a post annealing in a reducing atmosphere such as a H₂ atmosphere, carriers are substantially activated to further reduce resistivity. From these characteristics, it is expected that the metal oxide layer is applicable to wider range of applications in the future also from the viewpoints of increasing the area of transparent conductive films and using low-temperature growth. Further, effects of annealing in a reducing atmosphere shown in Examples to be later, can be said to be characteristic effects exhibited by containing dopants such as Nb or Ta.

Further, as shown in Examples to be described later, it has been confirmed that by carrying out film-forming is by a sputtering method at a room temperature and subsequently carrying out an annealing treatment, a Nb:TiO₂ film of amorphous state changes to a Nb:TiO₂ film containing anatase type polycrystals. Particularly, in the annealing treatment, it is unpredictable effect that the resistivity drastically decreases from about 10⁵ Ωcm to about 8×10⁻⁴ Ωcm. The activation ratio of Nb in this case was about 80% (n=1 to 2×10²¹ cm⁻³). Further, the hole mobility at a room temperature was about m=1 to 3 cm²/Vs by a sputtering method, and about m=6 to 12 cm²/Vs by a PLD method.

Thus, it has become clear by combining generally-usable sputtering method and an annealing treatment, a TiO₂ film having significantly reduced resistivity can be obtained. From these characteristics, it is expected that the metal oxide layer is applicable to wider range of applications in the future from the viewpoints of increasing the area of transparent conductive films and using low-temperature growth.

Application

The electric conductor of the present invention is applicable to a wide range of applications, and the electric conductor may be applicable to transparent electrodes of e.g. flat panel displays, solar cells or touch panels. Further, the electric conductor may be applicable to shielding of electric magnetic waves to be used for antireflective frills, films for preventing adhesion of particles due to static charge, antistatic films, heat-radiation-reflective glasses or UV-reflective glasses. By forming a multilayer film comprising a layer of SiO₂ and a TiO₂ layer doped with Nb, the multilayer film can be used also as an antireflective film.

Examples of application may be electrodes of dye-sensitized solar cells; transparent electrodes for display panels, organic EL panels, light-emitting elements, light-emitting diodes (LEDs), white LEDs or lasers; transparent electrodes of surface-emission type lasers; illumination devices; communication devices; applications transmitting light of only a predetermined wavelength region.

Further, as specific applications, the following applications may be mentioned: transparent electric conductive films in liquid crystal displays (LCDs); transparent electric conductive films in color filters; transparent electric conductive films in EL (electroluminescence) displays; transparent electric conductive films in plasma displays (PDPs); PDP optical filters; transparent electric conductive films for shielding electromagnetic waves; transparent electric conductive films for shielding near infrared rays; transparent electric conductive films for preventing surface reflection; transparent electric conductive films for improving color reproducibility; transparent electric conductive films for preventing breakage; optical filters; touch panels; resistance film type touch panels; electromagnetic induction type touch panels; ultrasonic type touch panels; optical type touch panels; electrostatic capacitance type touch panels; resistance film type touch panels for portable information devices; touch panels (inner touch panels) integrated with displays; solar cells; amorphous silicon (a-Si) type solar cells; fine crystal Si thin film solar cells; CIGS solar cells; dye-sensitized solar cells (DSCs); transparent electric conductive materials for preventing electrostatic of electric components; antistatic transparent electric conductive materials; light-control arterials; light-control mirrors; heating elements (surface heaters, electric heating glasses); electromagnetic wave shielding glasses.

### EXAMPLES

The present invention is described in further detail with reference to the following Examples, but the present invention is not limited to these Examples.

Measurement Method

The following measurement method was employed in the following Examples. The temperature in the measurements is a room temperature (20 to 25° C.) unless otherwise specified.
Sheet Resistance (unit: Ω): In (indium) electrodes are press-bonded onto a metal oxide layer of a sample in which the metal oxide layer is formed on a substrate, at an interval of 2 mm, and an electricity-voltage (I-V) characteristic was measured by using two terminals. The value of sheet resistance is calculated from the inclination of the I-V characteristic.
Transmittance, Reflectivity, Absorptivity and Spectrotransmittance Curve: Transmittance (%) and reflectivity (%) are measured by using a spectrophotometer manufactured by JEOL. Absorptivity (%) was obtained by subtracting the sum of the transmittance and the reflectivity thus measured from 100. Namely, reflectivity=100-transmittance-absorptivity. Spectrotransmittance curve was obtained by the measurement results of transmittance.
SEM (Scanning Electron Microscope) Image: A SEM (scanning electron microscope) manufactured by Hitachi, Ltd. was employed to obtain images of surfaces under the condition that the acceleration voltage was 10 kV.
Profile by X-Ray Diffraction (XRD): The profile was measured by an X-ray diffraction apparatus (XRD) manufactured by Bruker Corp.
Spectrum by X-Ray Photoelectron Spectroscopic Analyzer (XPS): The spectrum was measured by an X-ray photoelectron spectroscopic analyzer (XPS) manufactured by ULVAC-PHI, INC.
Atomic Force Microscope (AFM) Data: The data was measured by an atomic force microscope (AFM) manufactured by SEIKO.

### Example 1-1

Using a PLD apparatus shown in FIG. 2, a precursor layer was formed on a substrate under the following conditions

Substrate: A glass substrate of 0.5 mm thick made of non-alkali glass (manufactured by Asahi Glass Company, Limited, product name: AN100).

Film-forming method: PLD method

Partial pressure of oxygen at the time of film-forming: 1.33×10⁻² Pa (1×10⁻⁴ torr)

Target: A Nb:TiO₂ sintered product made of Ti_{0.94}Nb_{0.06}O₂

Substrate temperature: 250° C.

Nb content of the precursor layer obtained was 6 atomic %. Subsequently, post annealing was carried out under the following conditions to obtain a sample in which a metal oxide layer of 110 nm thick was formed on the substrate.

Post Annealing Conditions

Annealing atmosphere: After once evaluated to be a vacuum of 10⁻¹ Pa, hydrogen (H₂) was introduced to form H₂ atmosphere of 1.013×10⁵ Pa (1 atm).

Annealing temperature (substrate temperature): 500° C.

Annealing time: 100 min

Here, it took 5 minutes for the substrate temperature to rise from the room temperature to 500° C., and the substrate temperature was maintained at 500° C. for 100 minutes and let it cool to the room temperature.

With respect to the sample metal oxide layer obtained, resistivity, carrier density and hole mobility were measured. The results are shown in Table 1.

### Comparative Example 1

### Single Crystal Thin Film without Post Annealing

A single crystal thin film (hereinafter it may also be referred to as epitaxially grown anatase single phase or anatase type epitaxial film) of metal oxide having an anatase type crystal structure described in the above-mentioned Patent Document 1, was prepared.

Specifically, using a PLD apparatus shown in FIG. 1, an epitaxially grown anatase single phase of Nb:TiO₂ was formed on a substrate under the following conditions to obtain a sample. No post annealing was carried out.

Substrate: A single crystal substrate of SiTiO₃ having a substrate surface of (100) plane

Film-forming method: PLD method

Partial pressure of oxygen at the time of film-forming: 1.33×10⁻² Pa

Target: A Nb:TiO₂ sintered product made of Ti_{0.54}Nb_{0.06}O₂

Substrate temperature: 550° C.

The epitaxially grown anatase single phase thus formed had a film thickness of about 100 nm and a Nb content of 6 atomic %.

With respect to the epitaxially grown anatase single phase of the sample obtained, resistivity, carrier density and hole mobility were measured. The results were shown in Table 1.

### Comparative Example 1

### ITO Thin Film

Publicly known typical values of resistivity, carrier density and hole mobility of ITO thin film, are shown in Table 1.

TABLE 1

| | | Epitaxially | |
|---|---|---|---|
| | | grown anatase | |
| | | single phase | ITO |
| | | (Comparative | (Reference |
| | Example 1-1 | Example 1) | Example 1) |
| Resistivity | 1.6 × 10⁻³ | 2.4 × 10⁻⁴ | 2 × 10⁻⁴ |
| (Ωcm) | | | |
| Carrier | 1.5 × 10²¹ | 1.6 × 10²¹ | 8 × 10²⁰ |
| density (cm⁻³) | | | |
| Hole mobility | 2.5 | 16 | About 40 |
| (cm²V⁻¹s⁻¹) | | | |

The results in Table 1 show that the metal oxide layer of Example 1-1 is equivalent to the epitaxially grown anatase single phase having high crystallinity grown from a single crystal substrate in the resistivity and the carrier density, and shows good characteristics close to ITO.

### Example 1-2

### Film-Forming at Room Temperature without Cooling

A sample in which a metal oxide layer is formed on a substrate is obtained in the same manner as Example 1-1 except that a glass substrate is not heated at the time of forming the precursor layer and that the substrate temperature was a room temperature.

The resistivity of the metal oxide layer obtained was 5.1×10⁻⁴ Ωcm, which was lower than that of Example 1-1. This result shows that a metal oxide layer of low resistivity can be obtained by making substrate temperature a room temperature at a time of film forming by PLD method.

### Example 1-3

### Film-Forming at Room Temperature with Cooling

A sample in which a metal oxide layer was formed on a substrate was obtained under the same conditions of those of Example 1-2 except that cooling water was circulated to maintain the substrate temperature to be 25 to 50° C. at the time of forming precursor layer.

The resistivity of metal oxide layer obtained was 4.5×10⁻⁴ Ωcm which was further lower than that of Example 1-2. This result shows that the resistivity of metal oxide layer is further decreased by cooling the substrate at the time of film-forming at a room temperature by a PLD method.

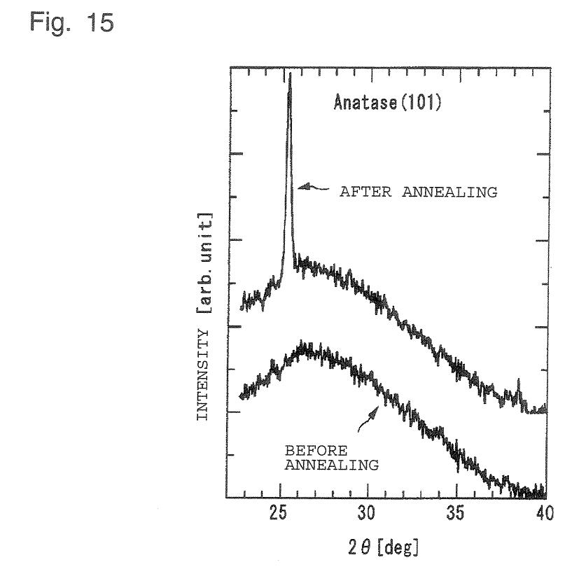

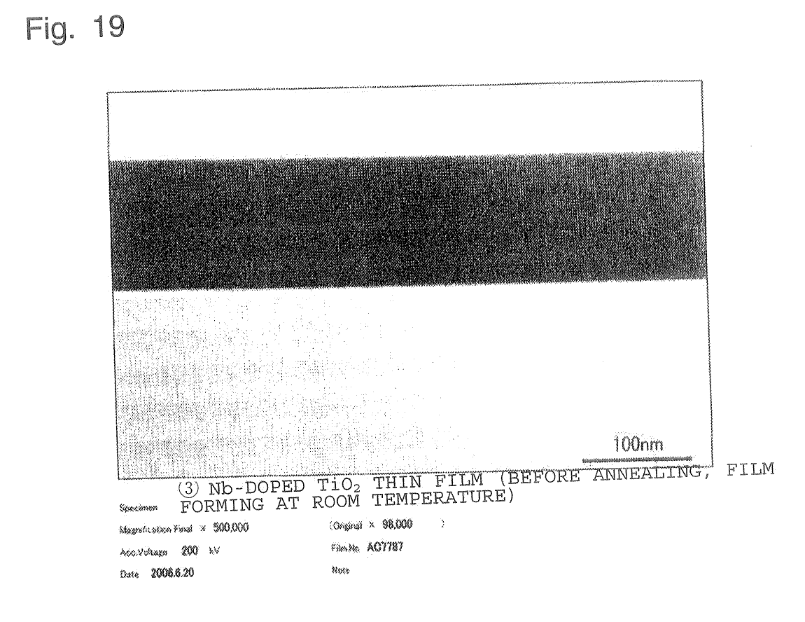

Further, as shown in FIG. 15(a) (Example 14) and FIGS. 19 to 21 (Example 19) to be described later, when the process is carried out under the conditions of this Example, the precursor layer before annealing becomes amorphous and the metal oxide layer after annealing becomes a state that a amorphous and polycrystals are mixed.

### Example 2

### Substrate Temperature at a Time of Film-Forming

In this Example, phase structures and resistivities (sheet resistances) before and after annealing were investigated with respect to samples produced under the conditions of Example 1-1 except that the precursor layers were formed at different substrate temperatures. The samples were produced under two type of annealing atmospheres that were the same H₂ atmosphere of Example 1-1 and a vacuum atmosphere (10⁻¹ Pa). Table 2 shows the results.

In Table 2, Tₛ indicates substrate temperature (unit: ° C.) at a time of forming the precursor layer, values in parenthesis indicate actually measured substrate temperatures, values without parenthesis indicate assumed substrate temperatures. Here, Examples of annealing in H₂ at a substrate temperature of 250° C. correspond to Example 1-1.

In Table 2, values on the left side of arrows in the columns show resistances (sheet resistances) before annealing and values on the right side of arrows indicate resistances after annealing. Here, as compared with Example 1-1, a sheet resistance of 1 kΩ corresponds to a resistivity of about 2.3×10^{-3 Ωcm.}

Further, signs “Anatase” or “Rutile” described under resistance value show that in an amorphous state phase in a metal oxide layer, anatase type crystals or rutile type crystals are confirmed to be present. Further, “slightly anatase” means that anatase crystals are confirmed in an amorphous state phase, and that most of the phase is in an amorphous structure.

Phase structure of metal oxide layer is to be described later with reference to e.g. SEM images.

TABLE 2

| | | | | After | | |
|---|---|---|---|---|---|---|
| Ts (° C.) | After annealing in H2 | | | annealing in vacuum | | |
| 200 | 1 MΩ | → | 700 Ω | 1 MΩ | → | 1.5 kΩ |
| | Anatase | | Anatase | Anatase | | Anatase |
| 250 (238) | 100 kΩ | → | 700 Ω | | | |
| | Anatase | | Anatase | | | |
| 250 | 100 kΩ | → | 700 Ω | 100 KΩ | → | 1.5 KΩ |
| | Anatase | | Anatase | Anatase | | Anatase |
| 300 (286) | 150 kΩ | → | 1 kΩ | 150 kΩ | → | 4 kΩ |
| | Anatase | | Anatase | Anatase | | Anatase |
| 350 (334) | 20 kΩ | → | 1.5 kΩ | 20 kΩ | → | 7 kΩ |
| | Anatase | | Slightly | Anatase | | Anatase |
| | | | Anatase | | | |
| 350 | 20 kΩ | → | 7 kΩ | | | |
| | Anatase | | Anatase | | | |
| 400 | 150 kΩ | → | 2 kΩ | | | |
| | Anatase | | Anatase | | | |
| 450 | 1 MΩ | → | 3.5 kΩ | | | |
| | Anatase | | Anatase | | | |
| 500 | 13 MΩ | → | 40 kΩ | | | |
| | Rutile | | Rutile | | | |

As shown in the results of Table 2, resistances before annealing were all low values of from 20 kΩ to 13 MΩ. Resistances after annealing was further lower than those before annealing. Decrease of resistance in H₂ is larger than decrease of resistance by annealing in vacuum.

Resistances in cases where anatase type crystals are present in amorphous state phases (substrate temperatures 200 to 450° C.) are lower than resistances in cases where rutile type crystals are present in amorphous state phases (substrate temperature 500° C.) in terms of resistances before and after annealing. Particularly, in cases where substrate temperatures were 250° C. or lower, an extremely low resistance of 700 Ω was obtained after annealing H₂.

### Example 3-1

### Film-Forming Atmosphere of Oxygen+Hydrogen

In this Example, the gas composition of the film-forming atmosphere of precursor layer was changed in the following manner in Example 1-1. A sample was produced under the same conditions of those of Example 1-1 except for this point, and sheet resistances before and after annealing was investigated.

Film-forming atmosphere: A mixed gas of oxygen and hydrogen

Oxygen partial pressure at a time of film-forming: 1.33×10⁻³ Pa

Hydrogen partial pressure at a time of film-forming: 1.33×10⁻³ Pa

Sheet resistances before and after annealing were all about 1 kΩ. As compared with the cases where the substrate temperature is 250° C., the sheet resistance before annealing in this Example is lower and the sheet resistance after annealing in this Example is higher. This result shows that when a precursor layer is formed in an atmosphere in which hydrogen is present, the resistance of the precursor layer before annealing is already low, and the resistance is not lowered by subsequent annealing.

### Example 3-2

### Film-Forming Atmosphere is Oxygen+Hydrogen

In this Example, the oxygen partial pressure and the hydrogen partial pressure at times of forming precursor layers were changed in the following manner in Example 3-1. The oxygen partial pressure in this Example is the same as that of Example 1-1. Except for this point, samples were produced in the same manner as Example 3-1 and sheet resistances were measured before and after annealing. As a result, sheet resistances before and after annealing were all about 1 kΩ in the same manner as Example 3-1.

Oxygen partial pressure at a time of film-forming: 1.33×10⁻² Pa

Hydrogen partial pressure at a time of film-forming: 1.33×10⁻² Pa

### Example 3-3

### Hydrogen Partial Pressure at a Time of Film-Forming

In this Example, samples were produced in the same manner as Example 1-1 except that substrate temperatures of precursor layers and oxygen partial pressures (P(O₂)) at times of film forming were different, and resistances (sheet resistances) before and after annealing were measured. Film-forming were carried out under two types of oxygen partial pressure conditions that were 1.33×10⁻² Pa being the same as that of Example 1-1 and 1.33×10⁻³ Pa. Annealing conditions were the same as those of Examples 1-1. Table 3 shows the results.

The notation system of Table 3 is the same as that of Table 2.

TABLE 3

P(O₂)) (Pa)

| | 1.33 × 10⁻² Pa | 1.33 × 10⁻³ Pa |
|---|---|---|
| Tₛ (° C.) | (1 × 10⁻⁴ Torr) | (1 × 10⁻⁵ Torr) |
| 250 | 100 kΩ → 700 Ω | 15 kΩ → 700 Ω |
| 350 | 20 kΩ → 7 kΩ | 20 kΩ → 10 kΩ |
| 400 | 150 kΩ → 2 kΩ | 100 kΩ → 20 kΩ |
| 450 | 1 MΩ → 3.5 kΩ | 300 kΩ → 40 kΩ |
| 500 | 13 MΩ → 40 kΩ | 70 kΩ → 20 kΩ |

According to the result in Table 3, the same tendency as that of Example 2 was observed even if the oxygen partial pressure was changed to 1.33×10⁻³ Pa. Namely, the resistances before annealing were all low and the resistances after annealing became further lower than those before annealing. Further, under the oxygen partial pressure P(O₂) in this range, there is no significant difference in resistance even if the oxygen partial pressure is different.

### Comparative Example 2

### No Dopant

In this Example, precursor layers were produced in the same manner as Example 1-1 except that a target at the time of forming precursor layer was changed to a TiO₂ sintered product not containing Nb and the substrate temperatures were two types that were 250° C. being the same as that of Example 1-1 and 350° C.

Subsequently, samples were produced by annealing in the same manner as Example 1-1 except that the annealing atmospheres were two types that were the same H₂ atmosphere as Example 1-1 and vacuum atmosphere (10⁻¹ Pa).

Surface structures and resistances (sheet resistances) before and after annealing of metal oxide layers obtained, were measured. Table 4 shows the results. The notation system of Table 4 is same as that of Table 2.

TABLE 4

| | | | | After |
|---|---|---|---|---|
| Ts (° C.) | After annealing in H₂ | | | annealing in vacuum |
| 200 | 70 kΩ | → | 100 kΩ | 70 kΩ → 350 kΩ |
| | Anatase | | Anatase | |
| 350 | 50 kΩ | → | 100 kΩ | 50 kΩ → 2 MΩ |
| | Anatase | | amorphous | |

The results in Table 4 show that as compares with the cases where the substrate temperatures are 250° C. and 350° C. in Table 2, the sheet resistance before annealing in this Example is lower but the sheet resistances are increased by annealing. These results indicate that dopant is effective for reducing the resistance by annealing.

### Example 4

### Temperature Dependence of Resistivity of Films Formed at 250° C. and 350° C.

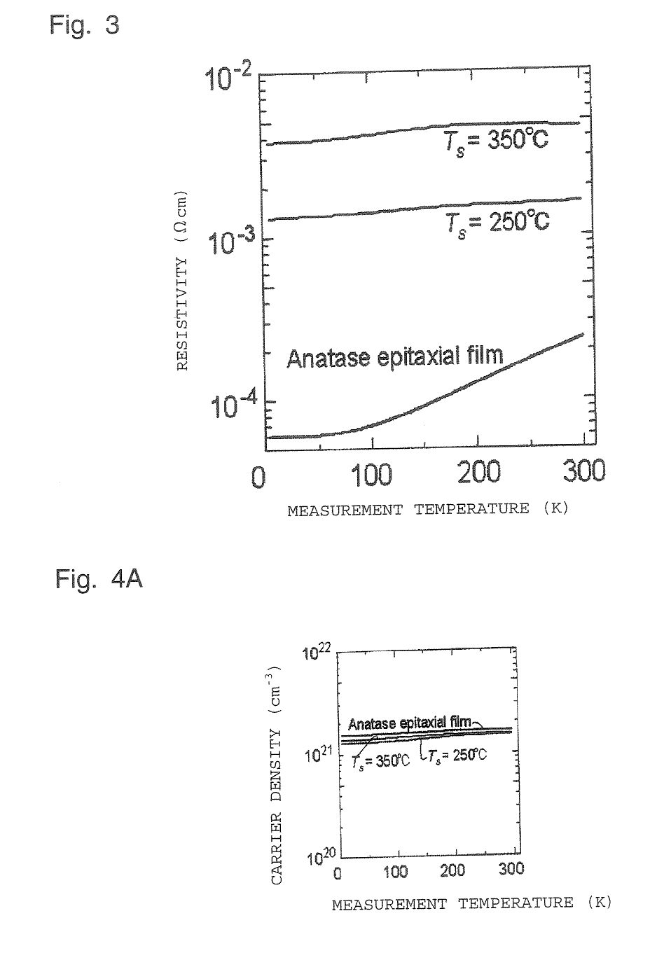

Samples were obtained in the same manner as Example 2 except that the substrate temperatures (Ts) at times of forming precursor layers were 250° C. (corresponding to Example 1-1) and 350° C. and annealed in H₂, and the resistivities of the samples at measurement temperatures of from 10 to 300 K were measured. The graph of FIG. 3(A) shows the results. In the graph, Ts indicates substrate temperature at times of film-forming, lateral axis represents measurement temperature and vertical axis represents resistivity.

Further, for comparison, the graph also shows results of the equivalent measurements with respect to epitaxially-grown anatase single phase obtained under the conditions of Comparative Example 1 (in the figure, referred to as “Anatase epitaxial film”).

The results of FIG. 3(A) show that the samples obtained under the conditions of Example 2 have lower resistances and better as compared with epitaxially-grown anatase single phases. Further, the results also shows that the resistivity decreases as the substrate temperature at a time of film-forming decreases.

### Example 5

### Carrier Density and Hole Mobility in Films Formed at 250° C. and 350° C.

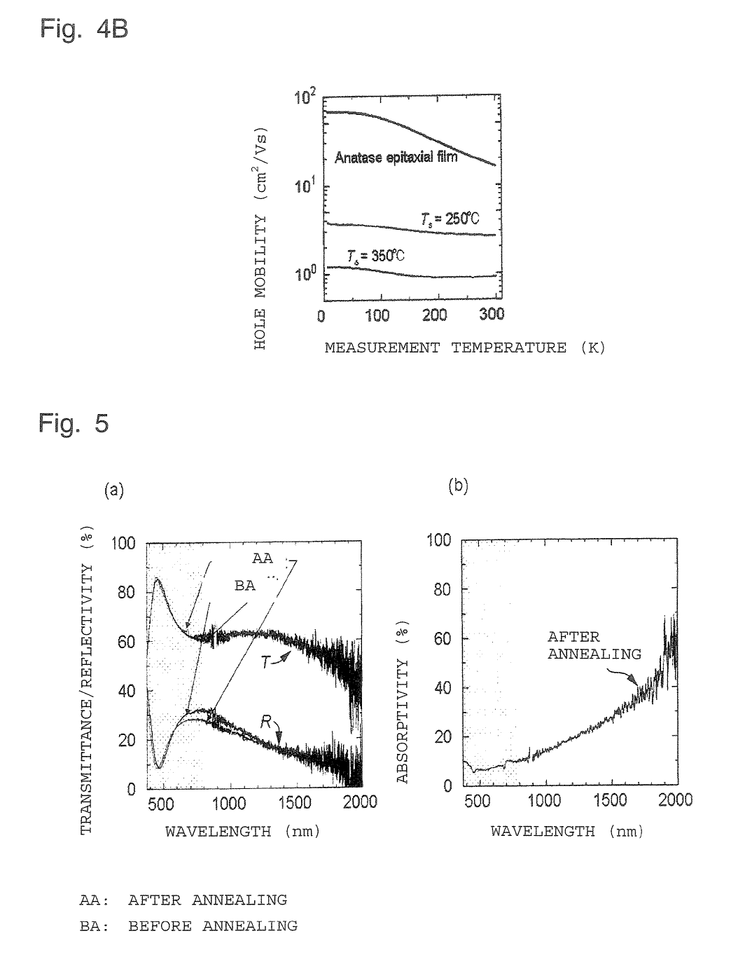

Samples were obtained in the same manner as Example 2 except that the substrate temperatures (Ts) at times of forming precursor layers were 250° C. (corresponding to Example 1-1) and 350° C. and annealed in H₂, and carrier 20 densities and hole mobilities of these samples were measured at measurement temperatures of 10 to 300 K. Graphs of FIG. 4A and FIG. 4B show the results. In these graphs, Ts indicates substrate temperature at the time of film-forming, lateral axis represents measurement temperature, vertical axis of FIG. 4A represents carrier density and vertical axis of FIG. 4B represents hole mobility.

Further, for comparison, the graphs also show the results of equivalent measurements with respect to epitaxially-grown anatase single phases of the samples obtained under the conditions of Comparative Example 1 (in the figures, referred to as “Anatase epitaxial film”).

Results of FIG. 4(A) show that activation rate of Nb is as high as about 90% in the samples (substrate temperatures were 250° C. and 350° C.) obtained under the conditions of Example 2, and that the samples were degenerate semiconductors in the same manner as anatase type epitaxially-grown metal oxide layers of Comparative Example 1.

Further, FIG. 4(B) shows that the metal oxide layers of the samples obtained under the conditions of Example 2 have lower hole mobilities than those of anatase type epitaxial films of Comparative Example 1, but have carrier densities close to those of anatase type epitaxially-grown metal oxide layers of Comparative Example 1.

### Example 6-1

### Transmittance T, Resistivity R and Absorptivity of a Sample Formed at 250° C.

With respect to samples obtained under the conditions of Example 1-1, in a state that a metal oxide layer of 110 nm thick was layered on a glass substrate, transmittance, reflectivity and absorptivity in a predetermined wavelength range were measured. Further, transmittance and reflectivity were measured in the same manner in a state that a precursor layer before annealing was layered on a glass substrate.

FIG. 5 shows the results. In FIG. 5(A), the lateral axis represents wavelength and the vertical axis represents transmittance or reflectivity. A symbol T in the figure indicates a graph of transmittance and R indicates a graph of reflectivity.

The results of FIG. 5 show that the metal oxide layers of the samples obtained under the conditions of Example 1-1, before and after annealing show good transmittance T, reflectivity R, absorptivity values particularly in visible light region.

### Example 6-2

### Transmittance T, Resistivity R and Absorptivity of Sample Formed at Room Temperature

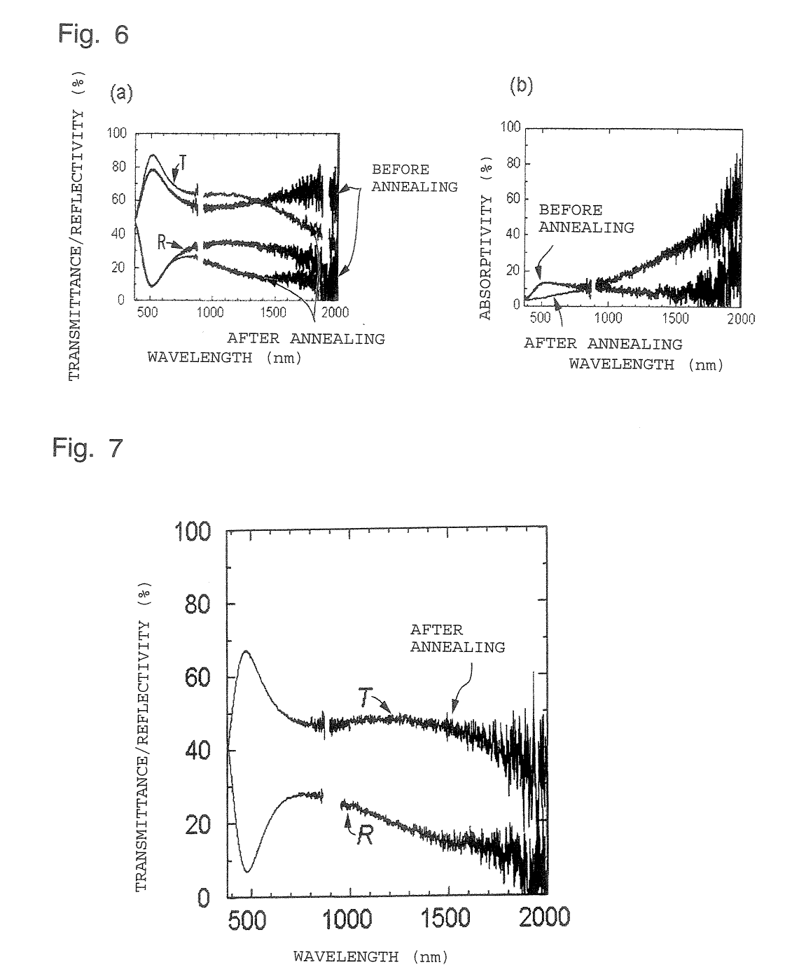

With respect to samples obtained under the conditions of Example 1-3, transmittances, reflectivities and absorptivities before and after annealing were measured in the same manner as Example 6-1. FIG. 6 shows the results.

The results of FIG. 6 show that when the precursor layer is formed at a room temperature, H₂ annealing produces significant increase of transmittance, significant decrease of reflectivity and significant decrease of absorptivity in visible light region.

### Example 6-3

### Transmittance T, Reflectivity R and Absorptivity of a Sample Formed at 350° C.

Samples were obtained in the same manner as Example 2 except that the substrate temperature (Ts) at the time of forming precursor layer was 350° C. and annealed in H₂, and transmittance and reflectivity after annealing were measured in the same manner as Example 6-1. FIG. 7 shows the results.

The results of FIG. 7 show that the metal oxide layers of the samples (substrate temperature 350° C.) obtained under the conditions of Example 2, show good values both in terms of transmittance and reflectivity particularly in visible light region.

### Example 7

### SEM Image

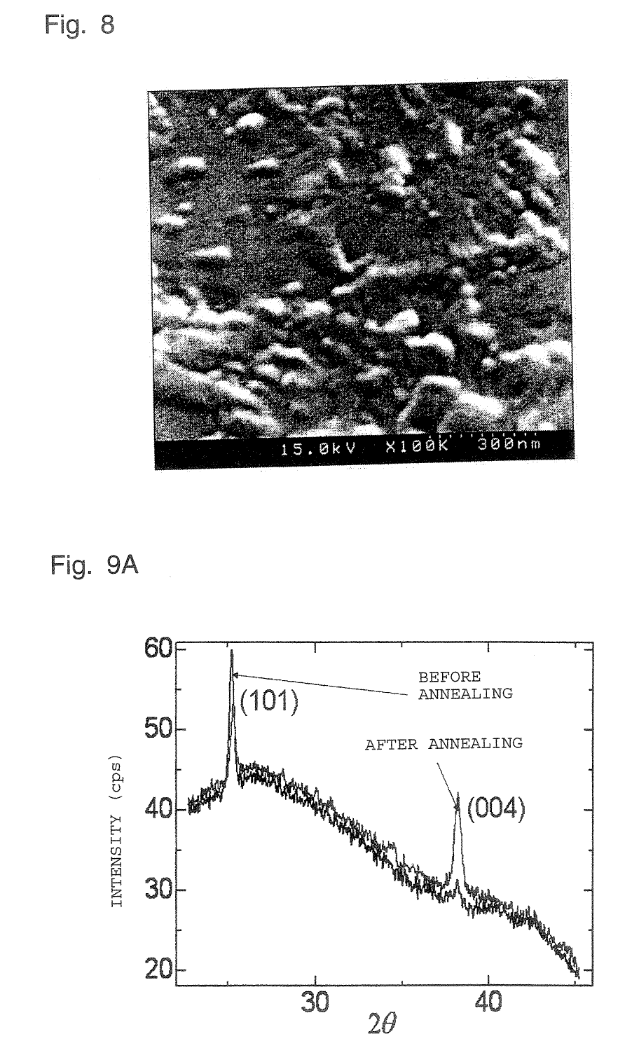

FIG. 8 shows an SEM image of a metal oxide layer in a sample obtained under the conditions of Example 1-1. According to this figure, it is understandable that grains are scarcely observed in the metal oxide layer and a slight amount of anatase type polycrystals are formed in an amorphous phase.

### Example 8

### XRD Profile

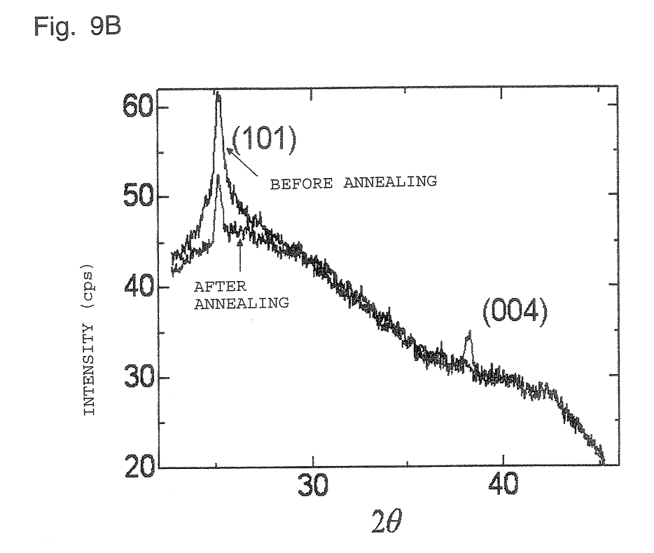

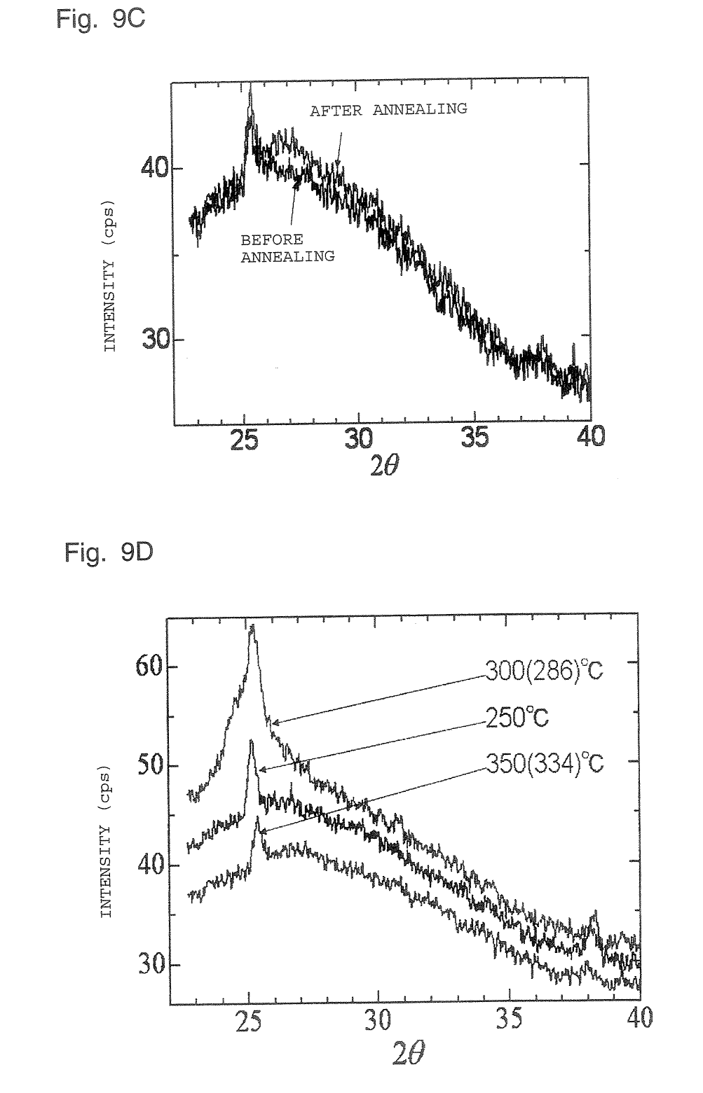

FIG. 9A, FIG. 9B and FIG. 9C show measurement results (XRD profiles) obtained by carrying out X-ray diffraction with respect to samples before and after annealing obtained in the same manner as Example 2 except that the substrate temperatures (Ts) at times of forming precursor layers were 200° C., 250° C. (corresponding to Example 1-1) and 350° C. and annealed in H₂. FIGS. 9A, 9B and 9C show measurement results of substrate temperatures of 200° C., 250° C. and 350° C. respectively.

Further, FIG. 9D shows XRD profiles after annealing of samples obtained in the same manner as Example 2 except that the substrate temperatures (Ts) at times of forming the precursor layers were 250° C., 300° C. and 350° C. and annealed in H₂. Temperatures in FIG. 9D are substrate temperatures at times of film-forming.

Generally speaking, peaks of (101) and (004) are peaks observed in anatase type polycrystals. Further, in complete polycrystals, the intensity ratio between (101) and (004) becomes 1,000:185. Accordingly, the results of FIG. 9(A) to 9(C) show that regardless of before or after annealing, the samples are in a state that amorphous phase and anatase type polycrystals are present as a mixture.

Further, the results of FIG. 9D show that even at different film-forming temperatures, the samples after annealing are in a state that anatase type crystals and amorphous are present as a mixture.

### Example 9

### XPS Spectrum

FIG. 10 shows measurement results of state spectrum of metal oxide layers of samples obtained under the conditions of Example 1-1 by an X-ray photoelectron spectroscopy analyzer (XPS). In this figure, a broken line shows the measurement result before annealing and a solid line shows the measurement result after annealing.

The result in this figure shows that in the metal oxide layer on a glass substrate, a peak of Ti³⁺ is observed after annealing and Ti³⁺ is contained in the film. Accordingly, it is understandable that the sample is reduced by annealing. Detection of such Ti³⁺ is a phenomena observed commonly to low resistance thin films obtained by the method of the present invention regardless of substrate temperature at a time of film-forming or film-forming method.

### Example 10

### AFM Data

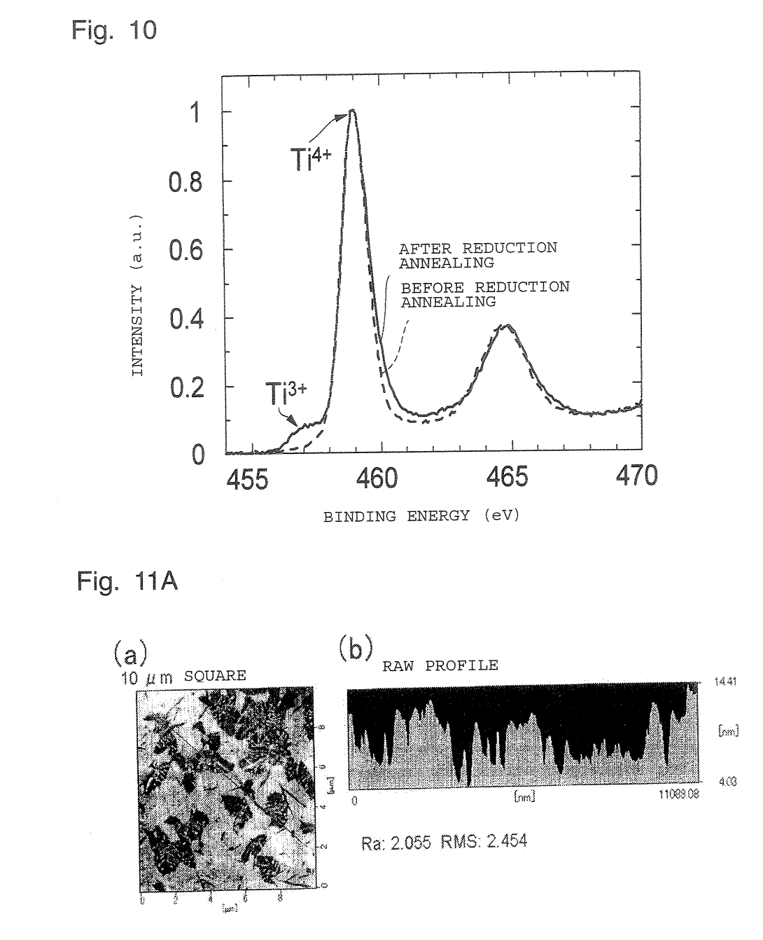

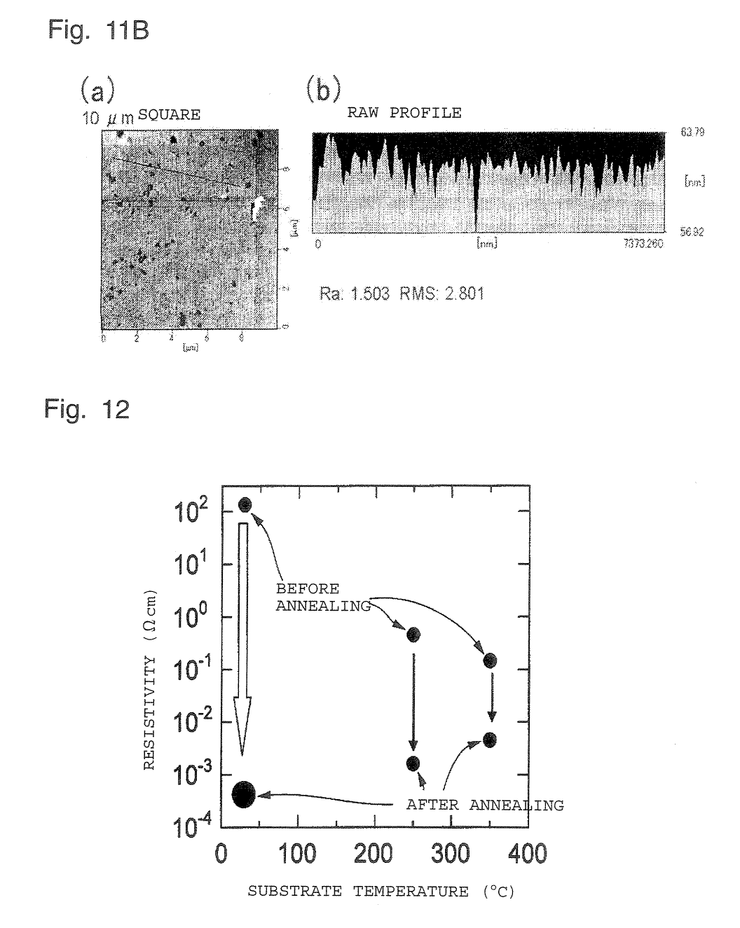

Samples were obtained in the same manner as Example 2 except that the substrate temperature (Ts) at times of forming precursor layers were 250° C. (corresponding to Example 1-1) and 350° C. and annealed in H₂, and metal oxide layers of the sample were measured by an AFM (atomic force microscope). FIGS. 11A and 11B show the results.

FIG. 11A shows the result of a sample of substrate temperature 250° C., and FIG. 11B shows the result of a sample of substrate temperature 350° C., wherein (a) shows an image of a surface of the metal oxide layer and (b) shows a Raw profile showing the state of surface irregularities. In the figures, Ra indicates a surface roughness value and RMS indicates average surface roughness value.

From the results of FIGS. 11A and 11B, it was understood that roughness on a surface of the metal oxide layer was about 10 nm and relatively flat surface was formed. The surface roughness is, although depending on application, preferably at most 20 nm.

Here, the sample (substrate temperature 350° C.) of FIG. 11B was analyzed by a method called electron backscattering diffraction (EBSD), and as a result, the sample contained little crystallized portions and most of the samples was amorphous (slightly anatase).

The above-mentioned EBSD (electron backscattering diffraction pattern) is a method for analyzing local crystal orientation of a material and is a method rapidly becoming widely used as combined with scanning electron microscope (SEM), and by combining such EBSD with an ultrahigh vacuum scanning electron microscope (UHV-SEM), further effective crystal orientation observation is realized.

### Example 11

### Change of Resistivity between before and after Annealing

FIG. 12 is a view showing change of resistivity between before and after annealing of a sample (film-forming at a room temperature) obtained under the conditions of Example 1-3 and samples obtained under the conditions of Example 2 except that the substrate temperatures (Ts) at times of forming precursor layers were 250° C. (corresponding to Example 1-1) and 350° C. annealed in H₂.

The results of the figure show that the change of resistivity by annealing becomes maximum when the substrate temperature at a time of forming a precursor layer is a room temperature. Namely, in terms of decrease of resistivity by annealing in H₂ atmosphere, a Ti_{0.94}Nb_{0.06}O₂ grown at a room temperature on a glass substrate shows larger decrease of resistivity as compared with a Ti_{0.94}Nb_{0.06}O₂ thin film formed under other substrate temperature conditions.

### Example 12

### Temperature Dependence of Resistivity

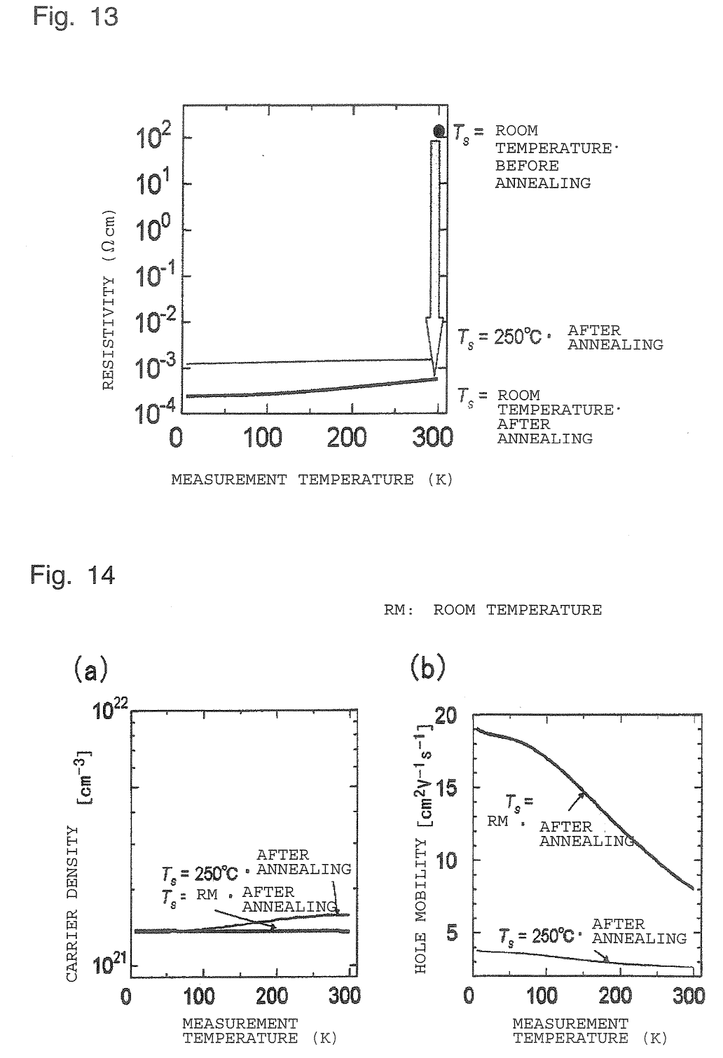

FIG. 13 is a view showing measurement results of temperature dependence of resistivity after annealing of a sample (substrate temperature Ts: room temperature) obtained under the conditions of Example 1-3 and a sample (substrate temperature Ts: 250° C.) obtained under the conditions of Example 1-1 within a measurement temperature range of 10 to 300 K. Further, FIG. 13 also shows a resistivity value (measurement temperature 300 K) before annealing of the sample obtained under the conditions of Example 1-3.

It has become clear from this figure that each of the samples obtained under the conditions of Example 1-1 and Example 1-3 showed little temperature dependence of the resistivity and a Ti_{0.94}Nb_{0.06}O₂ thin film after annealing showed slightly metallic behavior.

Further, although not shown in the figure, when the sample (substrate temperature Ts: room temperature, annealed in H₂) obtained under the conditions of Example 1-3 was subsequently annealed in oxygen, the resistivity was increased, but when the sample was annealed in a H₂ atmosphere, the resistivity becomes again in a low resistivity state of about 6×10⁻⁴ Ωcm.

### Example 13

### Temperature Dependence of Carrier Density and Hole Mobility

FIG. 14 is a view showing measurement results within a measurement temperature range of 10 to 300 K of temperature dependences of carrier density and hole mobility after annealing of a sample (substrate temperature Ts: room temperature) obtained under the conditions of Example 1-3 and a sample (substrate temperature Ts: 250° C.) obtained under the conditions of Example 1-1. FIG. 14(a) shows measurement results of carrier density and FIG. 14(b) shows measurement results of hole mobility.

The results of FIG. 14(a) shows that in each of the samples (substrate temperature: room temperature and 250° C.) obtained under the conditions of Example 1-1 and Example 1-3, at least 90% of Nb discharges a carrier (activated) and the sample are substantially degenerated.

### Example 14

### XRD Profile

FIG. 15 shows measurement results (XRD profile) obtained by carrying out X-ray diffraction before and after annealing of the sample (substrate temperature Ts: room temperature) obtained under the conditions of Example 1-3.

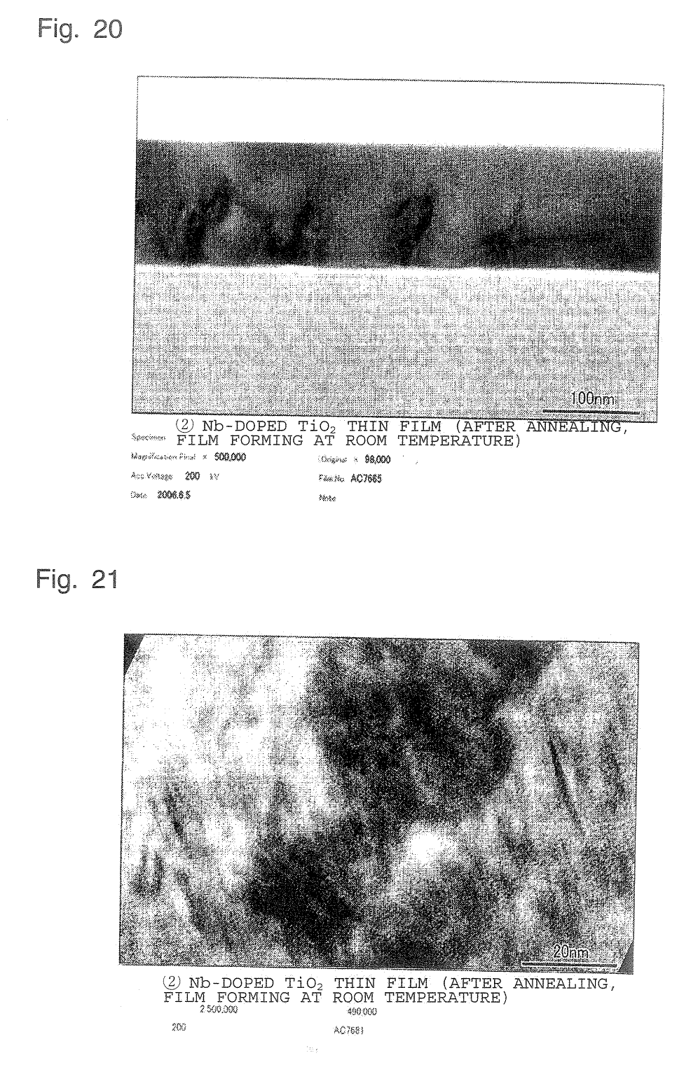

This result shows that the sample before annealing was amorphous and changed to be an anatase type polycrystals by annealing. Namely, the precursor layer formed at a room temperature under the conditions of Example 1-3 was in an amorphous state, and thereafter, by annealing the sample, the precursor layer was changed to be polycrystals. Here, as understandable from the cross-sectional TEM images shown in FIGS. 20 and 21 to be described later, under the production conditions of this Example, the sample after annealing is in a state that amorphous and polycrystals are present as a mixture.

### Example 15

### TEM Image of Film Formed at 250° C.

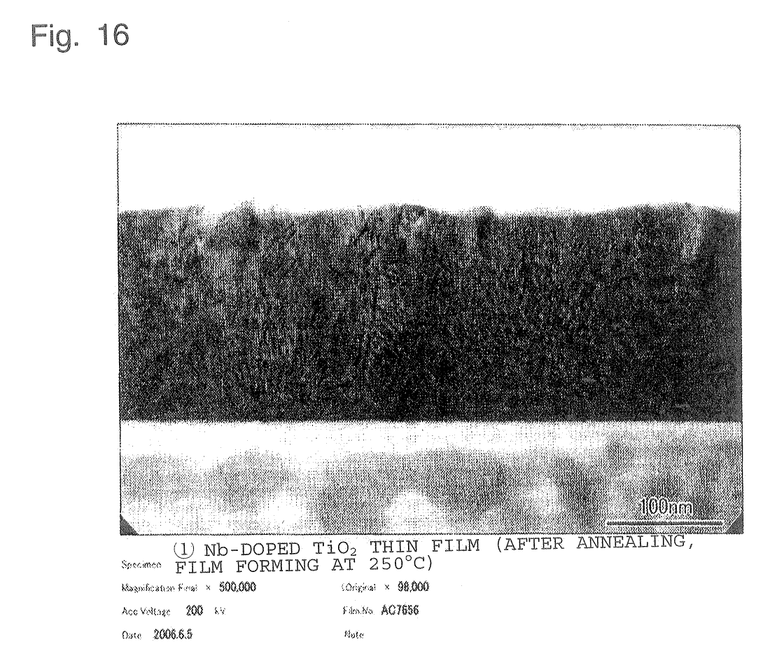

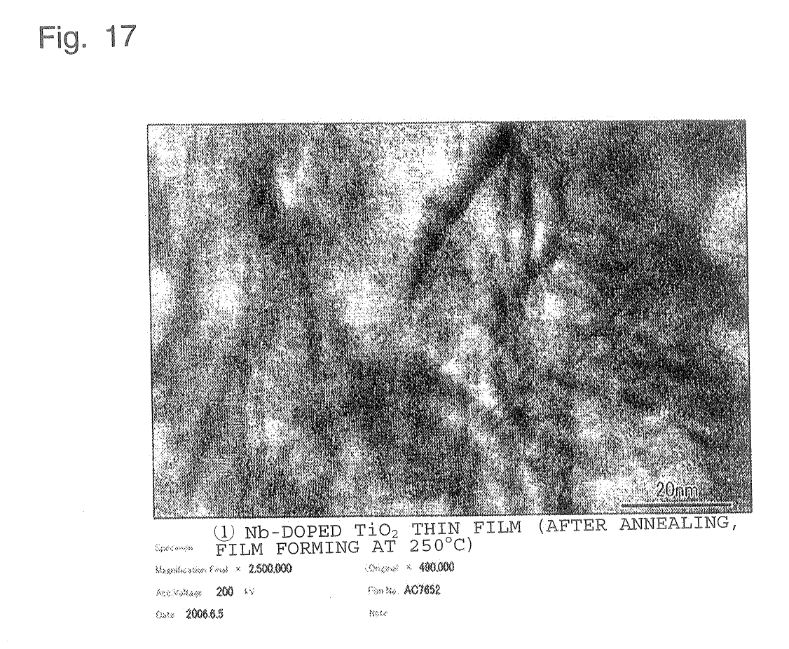

Cross-sectional TEM (transmission electron microscope) images of a metal oxide layer of a sample obtained under the conditions of Example 1-1 are shown in FIG. 16 and FIG. 17. The magnification in FIG. 16 is 5×10⁵X and the magnification in FIG. 17 is 2.5×10⁶X.

In the image of FIG. 16, it is understandable that a polycrystals thin film is formed and its grain boundaries can be observed. In the image of FIG. 17, every single grating can be observed.

Further, the above-mentioned SEM image shown in FIG. 8 (Example 7) or the analysis by EBSD employed in Example 10 shows that the surface of the sample is mostly amorphous, and the cross-sectional TEM image of this example shows that most of the inside of the layer is crystallized and amorphous portions are also present.

### Example 18

### Electron Diffraction Image of a Sample Formed at 250° C.

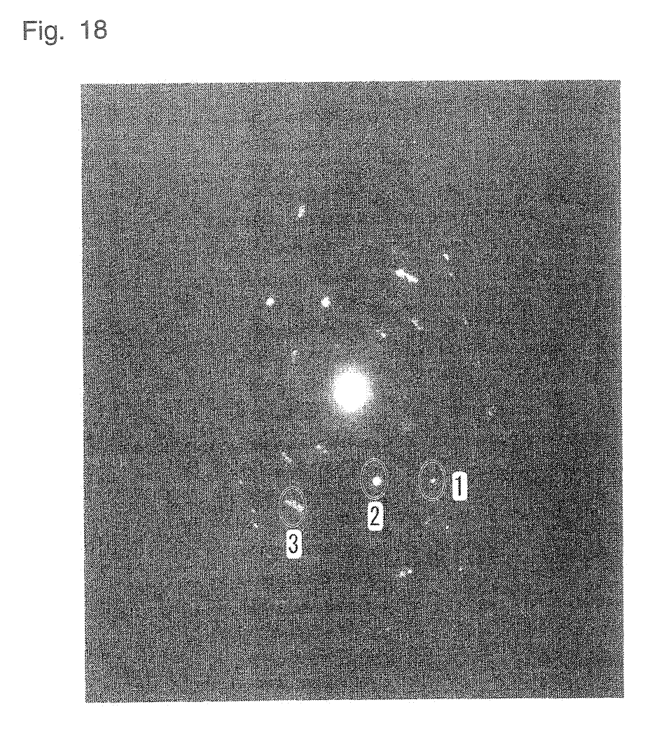

FIG. 18 shows an electron diffraction image of inside of a metal oxide layer of a sample produced under the conditions of Example 1-1. A plane interval d is obtainable by a formula Lλ/R. Here, R represents a distance from the center beam spot, L represents a camera length (653.3 mm in this Example) and λ represents wavelength of electron beam (0.0027 nm in this Example). A plane interval d represented by 1 in the figure was 1.73 Å and its plane direction was A(211) or 105. Further, the plane interval d represented by 2 in the figure was 2.39 Å and its plane direction was A(004) (“A” means anatase). Further, a plane interval d represented by 3 in the figure was 1.70 Å and its plane direction was A(211) or (105) (“A” means anatase).

These results show that inside of the crystals are anatase type crystals.

### Example 19

### TEM Image of a Sample Formed at a Room Temperature

A sample was produced under the conditions of Example 1-3 and cross-sectional TEM images of a precursor layer before annealing and a metal oxide layer after annealing were obtained.

FIG. 19 shows a cross-sectional TEM image before annealing, and its magnification is 5×10⁵X. This image shows that the sample was in a complete amorphous state.

FIGS. 20 and 21 show cross-sectional TEM images after annealing, wherein the magnification of FIG. 20 is 5×10⁵X and the magnification of FIG. 21 is 2.5×10⁶X. In the image of FIG. 20, defective structure of crystals such as dislocation can be observed and slight crystallization in the vicinity of the glass substrate is observed.

Further, as shown in the above-mentioned FIG. 15, since a peak of anatase (101) is observed in the XRD profile, it can be concluded that a Ti_{0.94}Nb_{0.06}O₂ thin film grown at a room temperature becomes to be in a state where amorphous and polycrystals are mixed when the film is annealed.

Little crystallization was observed in FIG. 20 whose magnification is 5×10⁵ X, while grids are observed in FIG. 21. The reason is considered to be because the sample was irradiated with concentrated electron beam when the magnification was set to 2.5×10⁵ X, which heats up the sample to produce annealing effect.

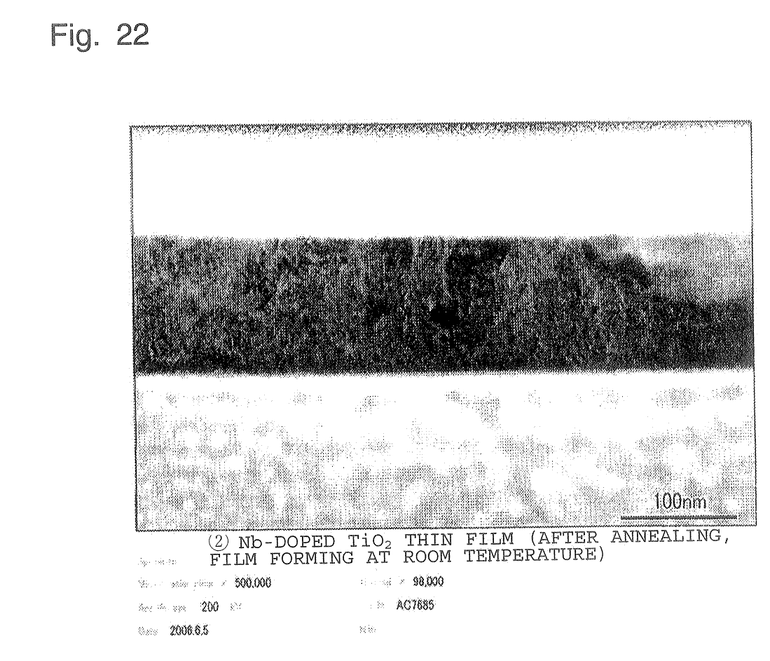

FIG. 22 is a cross-sectional TEM image observed at a magnification of 5×10⁵ X of the metal oxide layer (Nb doped TiO₂ thin film) that was observed as enlarged to be 2.5×10⁶ X in FIG. 21. This image shows that when the magnification was returned to 5×10⁵ X, crystallization progressed. This is considered to be because as described above, heating by narrowing the beam at the time of increasing the magnification to be 2.5×10⁵ X, provides the sample with an annealing effect.

From these results, it is considered that a Ti_{0.94}Nb_{0.06}O₂ thin film grown at a room temperature becomes to be in a state that amorphous and polycrystals are mixed when it is annealed in H₂ and its crystallization further progresses when the thin film is subsequently heated in the atmosphere.

### Example 20

### Annealing Time of a Sample Formed at a Room Temperature

### Example 20-1

### Resistivity

A precursor layer was formed on a substrate under the conditions of Example 1-3 except that the thickness of the precursor layer was changed to 100 nm.

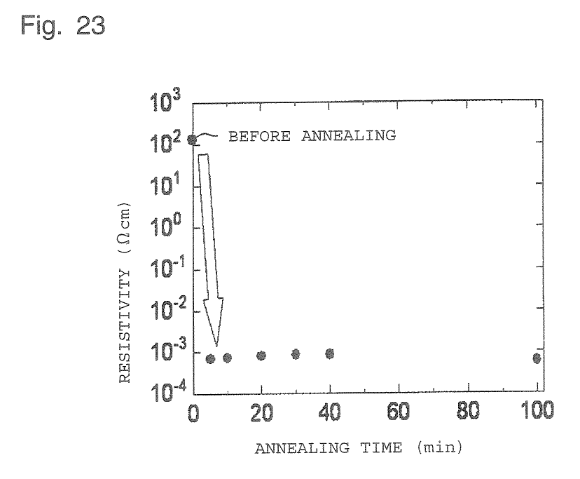

Subsequently, samples were produced in the same manner as Example 1-3 except that annealing times in the range of 5 min to 100 min were applied, and the resistivities of metal oxide layers were measured. FIG. 23 is a view showing the relation between resistivity and annealing time. FIG. 23 also shows a value of resistivity before annealing (annealing time: 0 min).

It has become clear from the results of the figure that the resistivity decreases 6 digits from that before annealing even if the annealing time is 5 min. This result indicates that the resistivity may be lowered even if the annealing time is within 5 min, but at least 5 min of annealing time is sufficient for making the resistivity low. Further, it has also become clear that the resistivity scarcely changes even if the annealing time is increased from 5 min.

### Example 20-2

### XRD Profile

A precursor layer was produced in the same manner as Example 20-1. Subsequently, four types of samples were produced, that were (1) a sample in an amorphous state that was not annealed, (2) a sample in a state that anatase polycrystals and amorphous were mixed, that was annealed for 5 min, (3) a sample in a state that polycrystals and amorphous were mixed, that was once annealed for 20 min and subsequently annealed twice for 10 min each time, and (4) a sample in a state that anatase polycrystals and amorphous were mixed, that was annealed for 100 min.

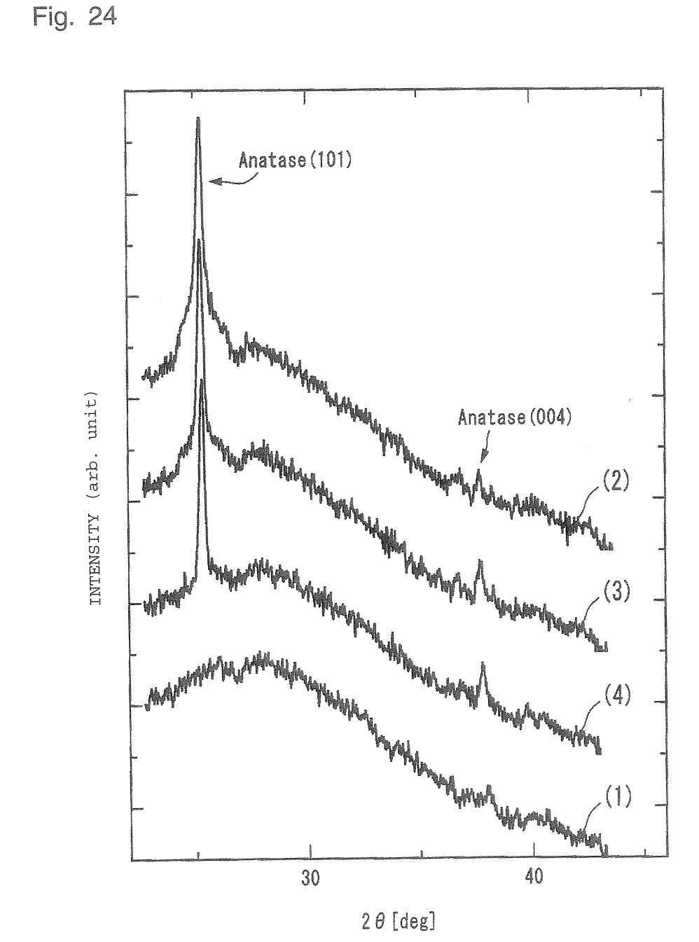

FIG. 24 shows a XRD profile obtained by carrying out XRD measurements of the four types of samples.

In the figure, with respect to the peak of (101), the Full-Width Half-Maximum (FWHM) of that of sample (2) was 0.330°, FWHM of that of the sample (3) was 0.292° and FWHM of that of the sample (4) was 0.257°. In the sample (1), the peak of (101) was not observed.

The results in the figure show that the amorphous of the precursor layer partially changes to polycrystals even if annealing time is 5 min. Further, although the peak intensity does not change by annealing time or number of annealings, but in terms of FWHM, the result was (2)>(3)>(4). Reduction of FWHM indicates increase of crystallinity (quality of crystal).

### Example 21

### Temperature-Rising Time at a Time of Annealing of a Film Formed at Room Temperature

### Example 21-1

### Resistivity

A precursor layer was formed on a substrate in the same manner as Example 1-3 except that the thickness of the precursor layer was changed to 100 nm.

Subsequently, post annealing was carried out under the following conditions to obtain a sample in which a metal oxide layer was formed on the substrate.

Annealing atmosphere: H₂ 100%, 1.013×10⁵ Pa (1 atm)

Substrate temperature: 500° C.

Annealing time: 10 min

Further, in Example 1-3, temperature-rising time to reach annealing temperature (500° C.) was 5 min but in this Example, the temperature rising time was changed to 5 min, 10 min and 20 min to produce three types of samples. The samples were maintained at 500° C. for 10 min and left to be cooled to a room temperature.

Resistivities of metal oxide layers of the samples obtained were measured.

As a result, the resistivity of a precursor layer not annealed was 63.3 Ωcm, the resistivity in the case of temperature-rising time 5 min was 5.5×10⁻⁴ Ωcm, the resistivity in the case of temperature-rising time 10 min was 5.8×10⁻⁴ Ωcm, and the resistivity in the case of temperature-rising time 20 min was 5.5×10⁻⁴ Ωcm. It was understood from these results that the temperature-rising time does not affect the resistivity after annealing.

### Example 21-2

### XRD Profile

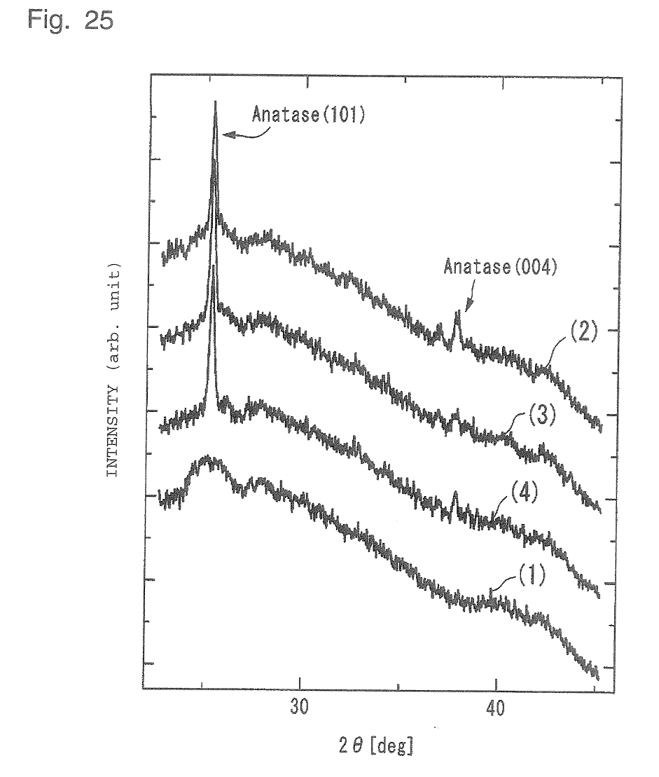

A precursor layer was produced in the same manner as Example 21-1. Subsequently, XRD measurement was carried out with respect to four types of samples that were (1) a sample not annealed and in an amorphous state, (2) a sample annealed at a temperature-rising time of 5 min, (3) a sample annealed at a temperature-rising time of 10 min, and (4) a sample annealed at a temperature-rising time of 20 min. FIG. 25 shows XRD profiles obtained.

In the figure, there was little difference among samples (2), (3) and (4) in terms of the peak of (101). The peak of (101) was not observed in the sample of (1).

This result also shows that there is little difference of crystal state after annealing, produced by the difference of temperature-rising time.

### Comparative Example 3

### No Dopant, Film-Forming at Room Temperature

A precursor layer (110 nm thick) was formed on a substrate under the conditions of Example 1-3 except that the target for forming the precursor layer was changed to a TiO₂ sintered product without containing Nb, and the precursor layer was annealed in the same manner to produce a sample.

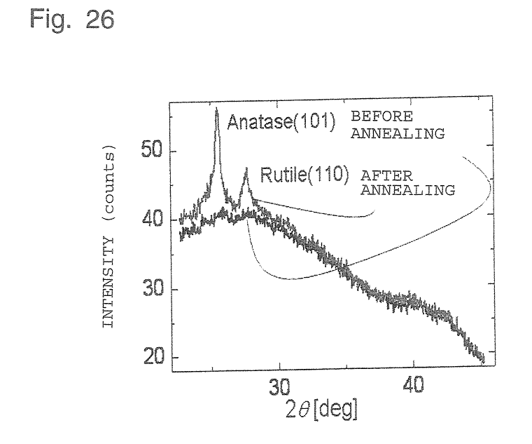

FIG. 26 shows measurement results (XRD profiles) obtained by carrying out X-ray diffraction at each time before and after annealing. Further, the resistivities before and after annealing were measured and, as a result, the resistivity of a precursor layer before annealing was 46.3 Ωcm and the resistivity of a metal oxide layer after annealing was 0.28 Ωcm.

As compared with the resistivities of the precursor layers and metal oxide layers formed at a room temperature and made of Nb-doped TiO₂ shown in the above-mentioned FIG. 12 (Example 11), reduction amount of resistivity by annealing in H₂ is significantly smaller in this Example. Further, in the XRD profiles of the precursor layer and the metal oxide layer formed at a room temperature and made of a Nb-doped TiO₂ shown in FIG. 15(a) (Example 14), it is observed that the precursor layer in an amorphous state changed to anatase type polycrystals by annealing, while in the XRD profile of this Example, there is not only a peak showing anatase type crystals but also a peak showing rutile type crystals after annealing. Resistivity of a metal oxide layer increases when rutile type crystals are formed.

These results show that Nb contributes to stabilization of anatase type crystals and suppresses generation of rutile type crystals. Namely, doping of Nb contributes to stabilization of anatase type crystals as well as reduction of resistivity.

### Example 22

### Film-Forming at Room Temperature, Annealing Temperature

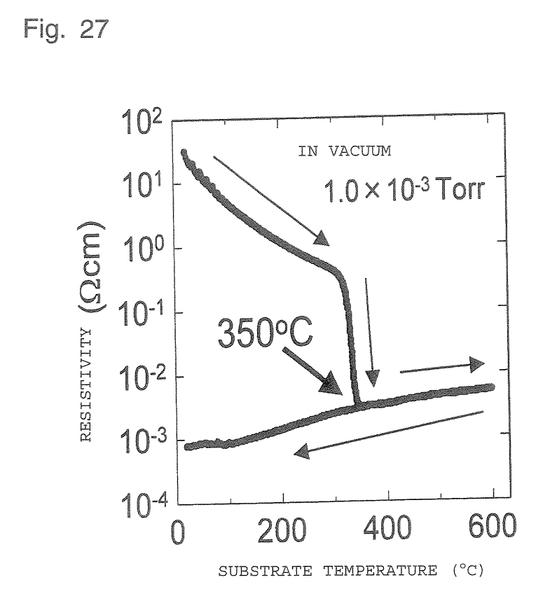

A precursor layer was formed under the conditions of Example 1-3. Subsequently, annealing was carried out by a method that in a vacuum of 1.33×10⁻¹ Pa (1×10⁻³ torr), the substrate temperature was gradually increased from a room temperature to 600° C. so that the temperature-rising time became 200 min, and after the substrate temperature reached 600° C., the substrate temperature was gradually lowered to a room temperature so that the temperature-falling time became 200 min. The resistivity of the metal oxide layer was measured at an interval of 1 sec. FIG. 27 shows the results.

As shown in the figure, as the substrate temperature rised from the room temperature, the resistivity gradually lowered and drastically lowered when the substrate temperature became about 320 to 350° C. Thereafter, the resistivity tended to gradually increase as the increase of substrate temperature, but was substantially leveled off.

This result shows that in an annealing in H₂, the resistivity can be satisfactory lowered if the annealing temperature (substrate temperature at the time of annealing) is at least 350° C.

### Comparative Example 2

### Upper Limit of Annealing Temperature

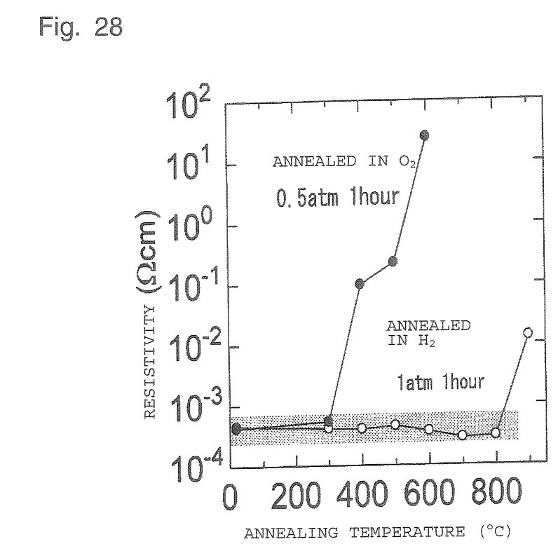

An epitaxially grown anatase single phase formed under the conditions of Example 1, was subjected to post annealing under different annealing temperatures (substrate temperatures) within a range of 250 to 850° C., and resistivities after the annealing were measured. The annealing time was 1 hour, and two types of annealing atmospheres were used, that were a H₂ atmosphere being the same atmosphere as Example 1-1 and an oxidating atmosphere having an oxygen partial pressure of 0.5×10⁵ Pa. FIG. 28 shows the results. In the figure, the measurement value at the annealing temperature 0° C. was the resistivity before annealing.

The results in this figure show that by the annealing in H₂ being a reducing atmosphere, low resistance was satisfactory maintained until the substrate temperature became 800° C. This result indicates that the stability of anatase type crystals are deteriorated if the annealing temperature exceeds 800° C. If the anatase type crystals are destroyed, transparency is is deteriorated.

Further, when the sample was annealed in the oxidating atmosphere (annealed in O₂), the resistivity significantly increased when the annealing temperature (substrate temperature) exceeded 300° C.

### Example 23

### Thermally Oxidized Si Substrate, Film-Forming at Room Temperature

### Example 23-1

### XRD Profile

Samples were produced under the conditions of Example 1-3 except that the substrate was changed to a thermally oxidized Si substrate and the thickness of the precursor layer was changed to 200 nm.

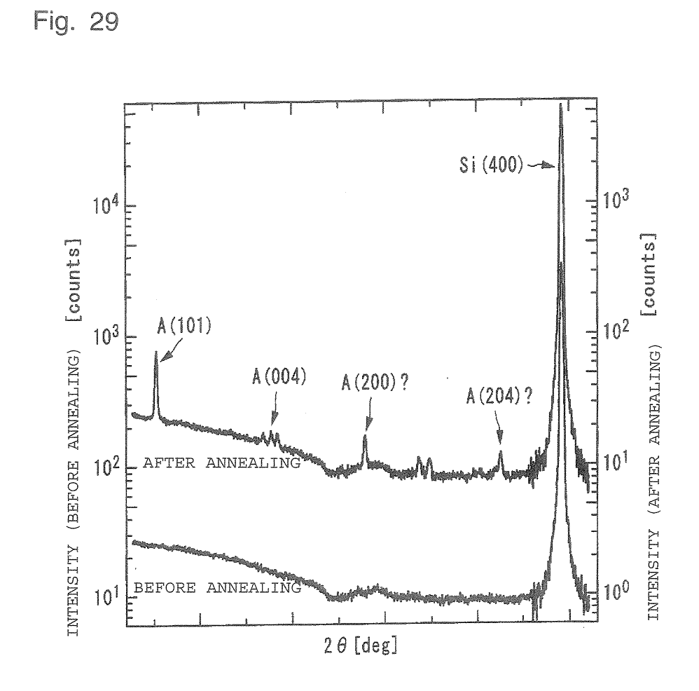

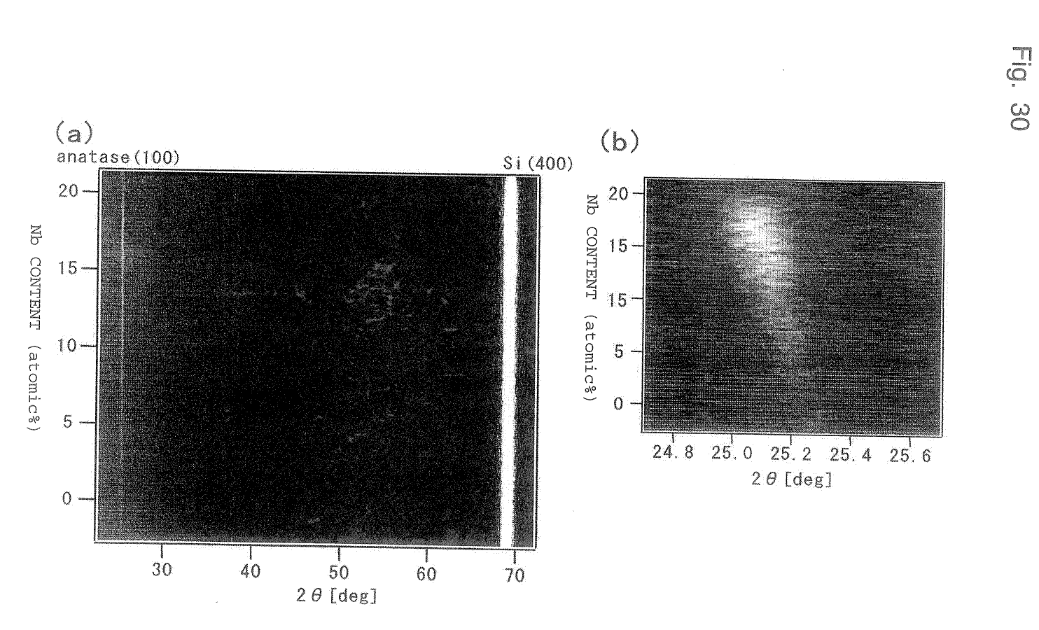

FIG. 29 shows the measurement results (XRD profiles) obtained by carrying out X-ray diffraction of the samples before and after annealing. Further, the resistances (sheet resistances) of the samples before and after annealing was measured, and as a result, the resistance of the precursor layer before annealing was 880 kΩ and the resistance of a metal oxide layer annealed in H₂ was 171 Ω.

From these results, it has become clear that in a case of employing a thermally oxidized Si substrate, in the same manner as a case of forming a metal oxide layer on a glass substrate, annealing in H₂ causes change from amorphous to polycrystals and causes significant decrease of resistance.

### Example 23-2

### Nb-Doping Amount

A composition-spread thin film (gradient composition film) of 200 nm thick in which Nb-doping concentration had a gradient of from 0 atomic % to 20 atomic %, was formed as a precursor layer on a thermally-oxidized Si substrate, by using a movable mask in combination with a PLD method at a time of forming the precursor layer. A metal oxide layer having a gradient of Nb concentration was formed in the same manner as Example 23-1 except for this point.

FIG. 30 shows measurement result (XRD profile) obtained by carrying out X-ray diffraction with respect to the metal oxide layer after annealing. FIG. 30(b) is an enlarged view showing the vicinity of the peak of anatase (101).

As shown in these figures, the peak (101) of anatase shifts in the low angle side as the concentration of Nb increases, which indicates solid solution of Nb. Accordingly, it was confirmed that the c-axis simply extends and at most 20 atomic % of Nb enters into crystals when anatase is formed from amorphous. This also indicates that Nb is not segregated on grain boundaries.

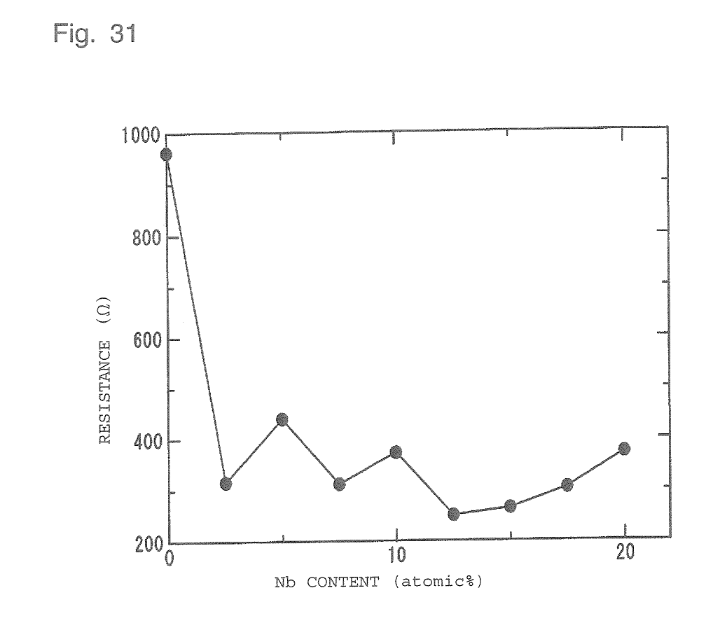

FIG. 31 is a graph showing the measurement result of resistance (sheet resistance) of the metal oxide layer having a gradient of Nb concentration obtained in the above.

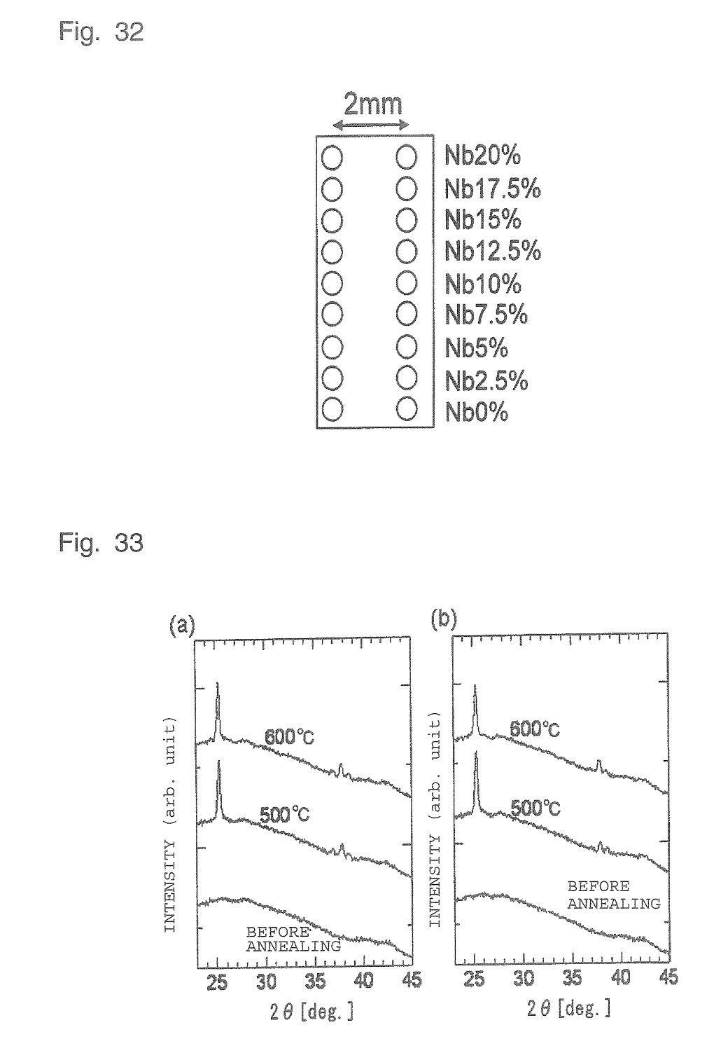

Measurement of resistance was, as shown in FIG. 32, carried out by such a method that In electrodes were press-bonded on the metal oxide layer at an interval of 1 mm along a direction of increasing Nb density, and at each of the press-bonded positions, an I-V measurement was carried out using two terminals, and the resistance was calculated from its inclination.

It has become clear from the result of FIG. 31 that the resistance sufficiently decreases if the Nb doping amount is at least 2.5 atomic %. Further, it is presumed that the resistance can be low even if the Nb doping amount is less than 2.5 atomic %.

### Example 24

### Vacuum State before Introducing Reducing Atmosphere

It has become clear that before annealing in H₂, by once evacuating the system by a pump before introducing hydrogen being a gas for producing a reducing atmosphere into the system, it is possible to form a metal oxide layer having lower resistance.

For example, in Example 1-3, before annealing in H₂, the system is once evacuated by a pump before introducing hydrogen into the system. The resistance of metal oxide layer after annealing in this case was 4.5×10⁻⁴ Ωcm. On the other hand, the resistance in a case where annealing was carried out in the same manner as Example 1-3 except that the vacuum state was not formed, was 5.0×10⁻⁴.

An example of producing a precursor layer by sputtering, is described as follows.

In the following Example of sputtering, “room temperature” of substrate temperature means a range of at least 25° C. and at most 80° C. In actual experiments, film-forming by sputtering was carried out under the condition that a substrate was not heated, and it was confirmed that the substrate temperature in the experiment was at least 70° C. and at most 80° C.

### Example 30

### Film-Forming at a Room Temperature vs. XRD Profile

Using a reactive DC magnetron sputtering apparatus, a precursor layer was formed on a substrate under the film-forming conditions shown in 1) of Table 5. As the substrate, a non-alkali glass (manufactured by Asahi Glass Company, Limited, product name: AN100) was employed.

Namely, in a vacuum chamber of a reactive DC magnetron sputtering apparatus, a Ti—Nb alloy containing 6 atomic % of Nb was set as a target, and a substrate was set. The distance (T/S) between the target and the substrate was 70 mm.

Subsequently, the vacuum chamber was evacuated to be 5×10⁻⁴ Pa or lower by a pump, and thereafter, Ar gas and O₂ gas were introduced into the vacuum system so that the ratio O₂/(Ar+O₂) became a predetermined value, and the pressure in the vacuum chamber was adjusted to be 1.0 Pa.

Then, in a state that magnetron magnetic field intensity was 1,000 G, a voltage was applied to the Ti—Nb alloy target at a wattage of 150 W, to form a titanium oxide film (precursor layer) doped with Nb on the substrate. The substrate was not heated so that the substrate temperature was a room temperature.

The precursor layer obtained had a film thickness of 150 nm and contained 6 atomic % of Nb. Subsequently, post annealing was carried out under the conditions shown in 2) of Table 5, to obtain a sample in which a metal oxide layer was formed on the substrate. Here, it took 5 min for the substrate temperature to reach 500° C. from the room temperature, and took 6 min to reach 600° C. The substrate temperature was maintained to be a predetermined annealing temperature for 1 hour, and left to be cooled to a room temperature. The metal oxide layer obtained has a film thickness of 140 nm and contains 6 atomic % of Nb.

Under two types of O₂/(Ar+O₂) ratios at a time of forming the precursor layer that were 10 vol % and 20 vol % and two types of annealing temperatures (substrate temperature) that were 500° C. and 600° C., samples were produced total under four types of conditions.

TABLE 5
1) Film-forming by reactive DC magnetron sputtering

| | |
|---|---|
| Target | Ti—Nb (Nb: 6 atomic %) alloy, |
| | 2 inch Φ |
| Discharge method | DC magnetron |
| Applied power to target | 150 W |
| Magnetron magnetic field | 1,000 G |
| intensity | |
| Sputtering gas | Ar + O₂(O₂/(Ar + O₂): 10 or 20 vol % |
| Sputtering pressure | 1.0 Pa |
| Substrate temperature | Room temperature |

2) Post annealing under reducing atmosphere after film-forming

| | |
|---|---|
| Atmosphere | H₂ 100% (1 × 10⁵ Pa) |
| Temperature | 500 or 600° C. |
| Annealing time | 1 hr |

FIG. 33 shows measurement results (XRD profiles) obtained by carrying out X-ray diffraction with respect is to a precursor before annealing and a metal oxide layer after annealing. FIG. 33(a) shows a case where the O₂/(Ar+O₂) ratio in the sputtering gas was 10 vol %, and FIG. 33(b) shows a case where that was 20 vol %. In the figures, the temperatures are annealing temperatures (500° C. or 600° C.). Vertical axis represents intensity (arbitrary unit).

In these figures, a peak of (101) seen in anatase type crystals are observed in the metal oxide layer after post annealing. Further, the figure shows that the precursor layer is in an amorphous state. These results show that an anatase type Nb:TiO₂ is obtained by post annealing. It is presumable that the metal oxide layer formed in this Example is in a state that anatase type crystals are present in an amorphous state phase.

### Example 31

### Substrate Temperature at a Time of Film-Forming vs. XRD Profile

Samples were produced in the same manner as Example 30 except that the substrate temperatures at times of forming the precursor layers were changed to a room temperature (corresponding to Example 30), 200° C., 350° C. and 500° C. and the annealing temperature was fixed to 600° C.

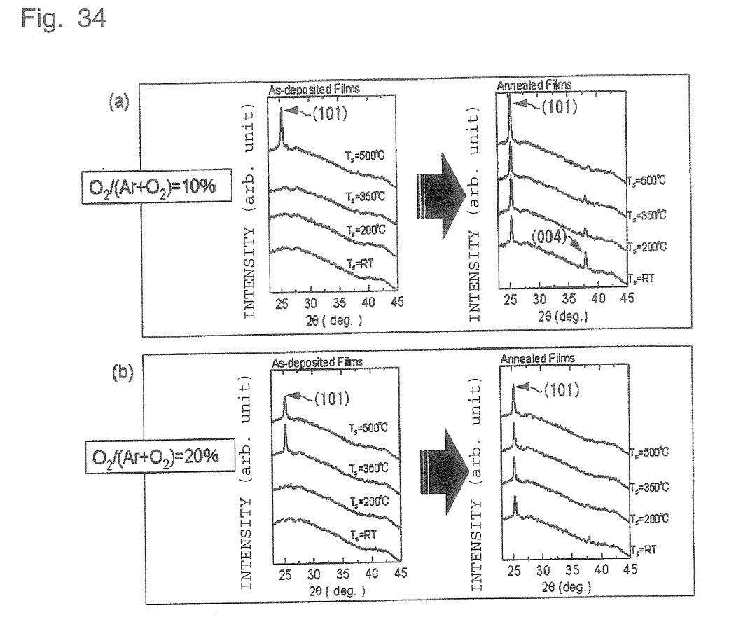

FIG. 34 shows measurement results (XRD profiles) obtained by carrying out X-ray diffraction with respect to precursors (left side of the arrows) before annealing and metal oxide layers (right side of the arrows) after annealing. FIG. 34(a) shows a case where the O₂/(Ar+O₂) ratio in the sputtering gas was 10 vol %, and FIG. 34(b) shows a case where that was 20 vol %. In the figures, the temperatures (Ts) are substrate temperatures at times of film-forming.

These figures show that the precursor layer before annealing formed at low substrate temperature is in an amorphous state and crystallization of the precursor layer progresses by annealing to form an anatase type structure. If the substrate temperature at the time of film forming is increased, a precursor layer crystallized in anatase type can be obtained. Further, when FIG. 34(a) and FIG. 34(b) are compared, it is understandable that as the O₂/(Ar+O₂) ratio is higher at a time of forming a precursor layer, the precursor layer is crystallized at lower substrate temperature.

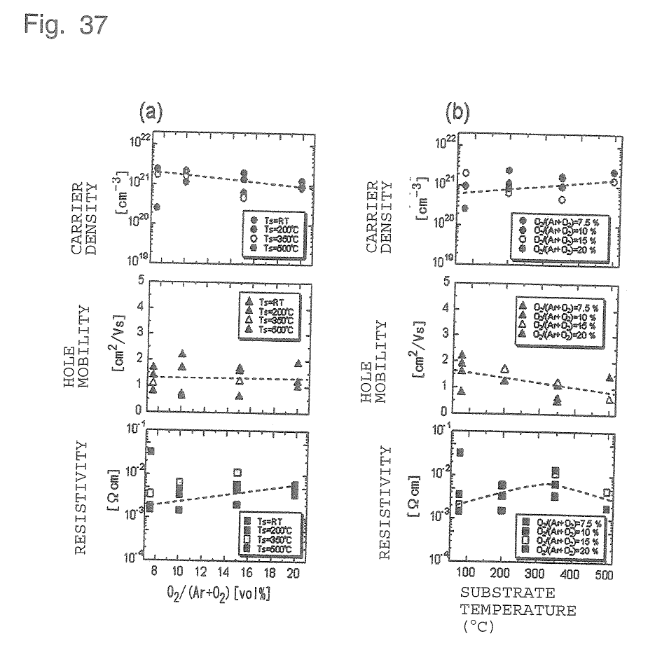

Further in FIG. 34, as the substrate temperature decreases, the peak (004) (a peak in the vicinity of 38°) in metal oxide layers after annealing becomes larger. As shown in FIG. 37 (Example 34) to be described later, there is data showing that hole mobility increases as the substrate temperature decreases. These data indicate that mobility depends on orientation of crystal axis.

### Example 32

### Presence or Absence of Dopant vs. XRD Profile

### Example 32-1

### Nb Contained

A sample was produced in the same manner as Example 30 except that the O₂/(Ar+O₂) ratio in the sputtering gas was 10 vol % and the annealing temperature was fixed to 600° C.

### Example 32-2

### Nb not Contained

A sample was produced in the same manner as Example 32-1 except that the target made of Ti not containing Nb is changed to a metal plate.

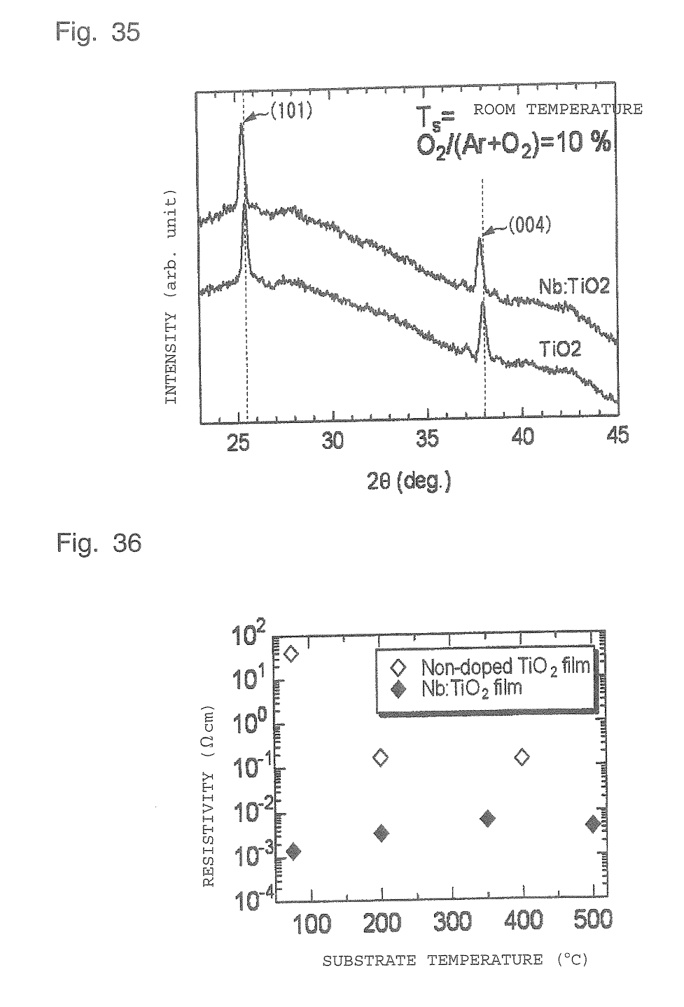

FIG. 35 shows measurement results (XRD profiles) obtained by carrying out X-ray diffraction with respect to a metal oxide layer (Nb:TiO₂ film) obtained under the conditions of Example 32-1 and a metal oxide layer (TiO₂ film) obtained under the conditions of Example 32-2.

This figure shows that the (101) peak and the (004) peak are shifted to low angle side by Nb doping. This result shows that crystal gratings are expanded. Since the radius of Nb⁵⁺ ion is 0.069 nm and the radius of Ti⁴⁺ ion is 0.068 nm, substitution of Ti sites by Nb atoms is considered to expand crystal gratings. Accordingly, it can be confirmed from the XRD profile of the figure that in a Nb-doped TiO₂ film, Nb substitutes Ti.

### Example 33

### Presence or Absence of Dopant, Substrate Temperature vs. Resistivity

### Example 33-1

### Nb Contained

Samples were produced in the same manner as example 30 except that the substrate temperature at times of forming precursor layers were changed to a room temperature (corresponding to Example 30), 200° C., 350° C. and 500° C., and the O₂/(Ar+O₂) ratio in the sputtering gas was 10 vol % and the annealing temperature was fixed to 600° C.

### Example 33-2

### Nb not Contained

Samples were produced in the same manner as Example 33-1 except that the target made of Ti not containing Nb was changed to a metal plate. Here, the substrate temperatures for forming the precursor layers were three types that were a room temperature, 200° C. and 400° C.

FIG. 36 is a view showing the measurement results of resistivities with respect to metal oxide layers (Nb:TiO₂ films, represented by ♦ in the figure) obtained under the conditions of Example 33-1 and metal oxide layers (TiO₂ films represented by ⋄ in the figure) obtained under the conditions of Example 33-2.

It is understandable from this figure that the resistivity decreases by 2 to 4 digits by doping Nb. Accordingly, it can be confirmed by XRD that Nb substitutes Ti as described above, and further, it can be confirmed by this figure that the substituting Nb efficiently behaves as a donor.

### Example 34

### Substrate Temperature, Sputtering Gas Composition vs. Resistivity, Carrier Density, Hole Mobility

16 Types of samples were produced in the same manner as Example 30 except that the substrate temperatures at times of forming precursor layers were four types that were a room temperature (corresponding to Example 30), 200° C., 350° C. and 500° C.; the O₂/(Ar+O₂) ratios in the sputtering gases were four types that were 7.5, 10 (corresponding to Example 30), 15 and 20 (corresponding to Example 30) vol %; and the annealing temperature was fixed to 600° C.

With respect to metal oxide layers of the samples obtained, resistivity, carrier density and hole mobility were measured. FIG. 37 shows the result.

FIG. 37(a) is a view in which the lateral axis represents oxygen density in the sputtering gas, FIG. 37(b) is a view in which the lateral axis represents the substrate temperature at times of film-forming, and vertical axes of both of these figures represent carrier density, mobility and resistivity. FIGS. 37(a) and 37(b) are graphs in which the same data are plotted, and they are figures substantially equivalent to each other except for parameters.

In the 16 types of samples obtained in this Example, the resistivities of precursor layers before annealing were all about 10⁵ Ωcm. As shown in FIG. 37, in the 16 types of samples obtained, the minimum resistivity was 1.1×10⁻³ Ωcm. It is understandable from these results that the resistivity decreases by 8 digits by post annealing under specific conditions.

It is understandable from FIG. 37(a) that (1) carrier density tends to decrease as O₂/(Ar+O₂) increases, (2) mobility scarcely depends on O₂/(Ar+O₂), and (3) increase of resistivity by the increase of O₂/(Ar+O₂) is mainly caused by decrease of carrier density.

It is understandable from FIG. 37(b) that (1) carrier density increases as substrate temperature increases, (2) mobility decreases as substrate temperature increases, and (3) from these two relations, resistivity is maximized at a substrate temperature in the vicinity of 350° C.

These results show that when the oxygen density O₂/(Ar+O₂) in the sputtering gas is at least 7.5 vol % and at most 20 vol %, it is possible to obtain a Nb:TiO₂ film whose resistivity is, in greater or lesser degrees, significantly reduced by annealing. Further, when the oxygen density is set to be at least 10 vol % and at most 20 vol %, it is possible to obtain a Nb:TiO₂ film having a resistivity of at most about 10⁻² Ωcm without depending on substrate temperature in the sputtering step.

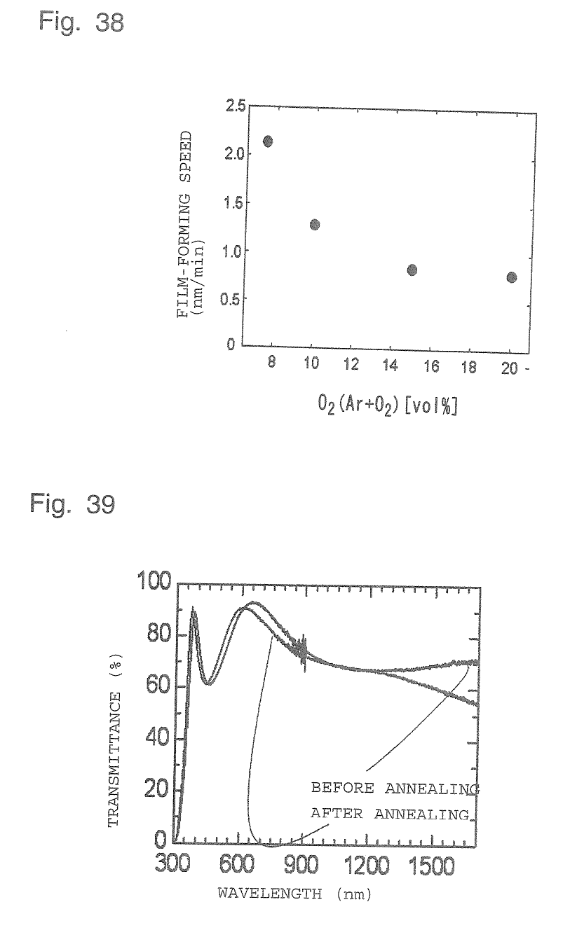

Here, FIG. 38 shows the relation between film-forming speed and the O₂/(Ar+O₂) ratio, and the figure shows that as O₂/(Ar+O₂) is lower, film-forming speed is larger and the film-forming speed does not change so much when O₂/(Ar+O₂) is 15 vol % or more. Accordingly, the oxygen density O₂/(Ar+O₂) in the sputtering gas is preferably 10 vol % for the reasons that high-speed film-forming is possible and a Nb:TiO₂ film of low resistance can be obtained.

Here, the measurement method of film-forming speed (unit: nm/min) was such that the film thickness (unit: nm) after film-forming was actually measured, and the film thickness was divided by a time (unit: min) required for film-forming, to obtain the film-forming speed.

Further, when the substrate temperature in the sputtering step is at least a room temperature and at most 500° C., it is possible to obtain a Nb:TiO₂ film whose resistivity is, in greater or lesser degrees, significantly reduced by annealing. When the substrate temperature is set to be at least 200° C. and at most 500° C., it is possible to obtain a Nb:TiO₂ film having a resistivity of at most about 10⁻² Ωcm without depending on substrate temperature in the sputtering step. Further, as shown in the above-mentioned FIG. 34 (Example 31), since the intensity of XRD (004) peak of Nb:TiO₂ film increases and high mobility is expected to be obtainable, the substrate temperature in the sputtering step is preferably be set to a room temperature.

### Example 35

### Transmittance, Resistivity, Carrier Density and Hole Mobility of Films Formed at Room Temperature

Samples were produced under the conditions of Example 30 except that the O₂/(Ar+O₂) ratio in the sputtering gas was 10 vol % and the annealing temperature was fixed to 600° C. (same conditions of Example 32-1).

Table 6 is a table showing measurement results of electrical characteristics (resistivity, carrier density and mobility) and film thickness of a precursor layer (insulation film) before annealing and a metal oxide layer (Nb:TiO₂ film, electric conductive film) after annealing. Since the precursor layer before annealing had extremely high resistance, it was difficult to measure its carrier density and mobility.

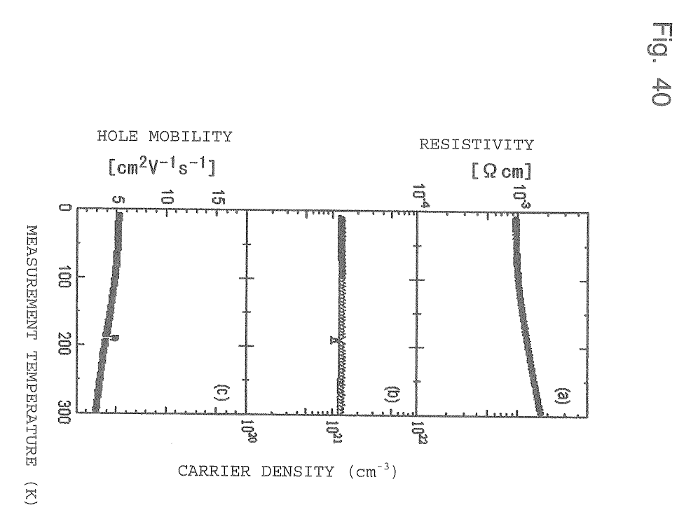

FIG. 39 is a view showing measurement results of spectral transmittance of the precursor layer (insulation film) before annealing and the metal oxide layer (Nb:TiO₂ film, electric conductive film) after annealing in the sample obtained.

TABLE 6

| | Before annealing | After annealing |
|---|---|---|
| Resistivity (Ωcm) | 10⁵ or less | 1.4 × 10⁻³ |
| Carrier density (cm⁻³) | — | 2.0 × 10²¹ |
| Mobility (cm²V⁻¹s⁻¹) | — | 2.2 |
| Film thickness (nm) | 150 | 140 |

These results show that there is little difference between the precursor layer before annealing and the metal oxide layer after annealing in terms of transmittance in the visible light region (wavelength 380 nm to 780 nm). Accordingly, it has become clear that even in a case where the metal oxide layer is applied to an application requiring transparency, annealing causes no practical problem. Further, these data also show that the transmittance is decreased by annealing in the near infrared region (wavelength 800 nm or longer). This indicates that the sample after annealing shows electric conductivity and free electrons contributing to the electric conductivity causes light absorption. Namely, the measurement result of transmittance also supports that the metal oxide layer after annealing has electric conductivity.

Further, both of the samples before and after annealing show good transmittance particularly in visible light region, which shows that the sample is excellent in transparency.

### Example 36

### Temperature Dependence of Resistivity, Carrier Density and Hole Mobility of Films Formed at Room Temperature

Samples were produced under the conditions of Example 30 except that the O₂/(Ar+O₂) ratio in the sputtering gas was 10 vol % and annealing temperature was fixed to 600° C. (the same conditions of Example 32-1).

FIG. 40 is a view showing measurement results of electrical characteristics (resistivity, carrier density and mobility) of metal oxide layers of the samples obtained at different measurement temperatures within the range of 10 to 300 K. In FIG. 40, (a) shows resistivity, (b) shows carrier density and (c) shows hole mobility that are measurement results.

It is understandable from this figure that carrier density does not depend on measurement temperature. Namely, the metal oxide layer obtained shows metallic behavior. The activation ratio was about 80%. Further, it is understandable that the hole mobility decreases as the temperature increases. Effect of phonon can be observed in the vicinity of room temperature. These results show that the metal oxide layer obtained is a degenerated semiconductor. This characteristic is common to the metal oxide layer (Nb:TiO₂ film) formed by the PLD method shown in the above-mentioned Example.

### Example 37

### Distance between Target and Substrate at a Time of Film-Forming vs. XRD

Samples were produced in the same manner as Example 30 except that the distance T/S between target and substrate in a chamber in a sputtering apparatus at times of forming precursor films, were 50 mm or 75 mm (i.e. two conditions), and the O₂/(Ar+O₂) ratio in the sputtering gas was fixed to 10 vol %.

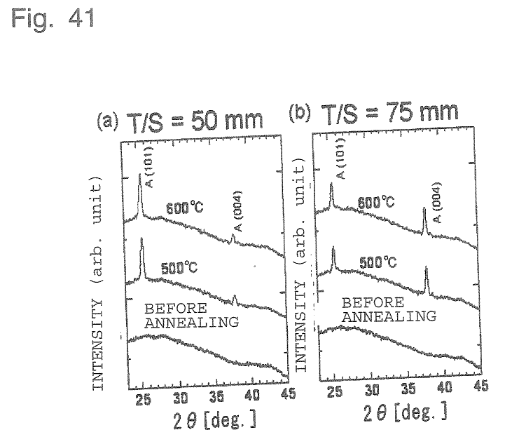

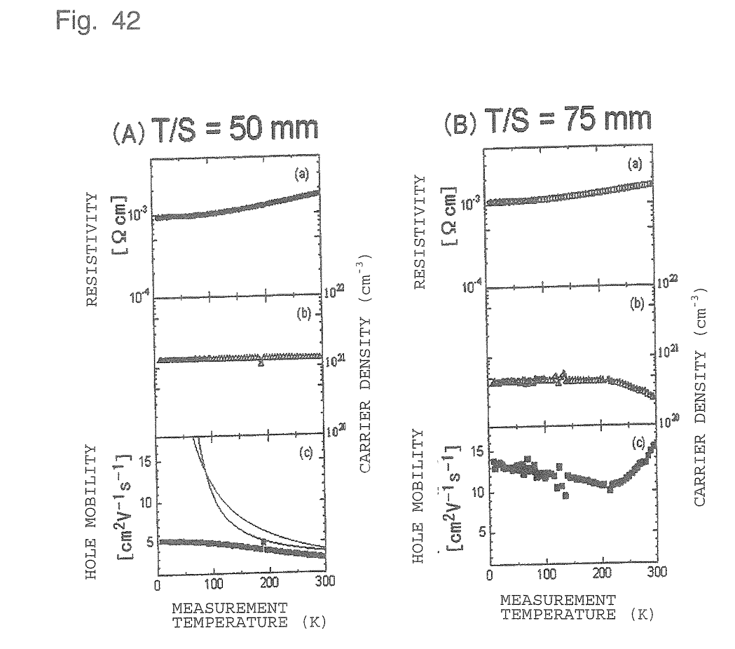

FIG. 41 shows measurement results (XRD profiles) obtained by carrying out X-ray diffraction with respect to precursor layers before annealing and metal oxide layers after annealing. FIG. 41(a) shows a case where the distance T/S between target and substrate was 50 mm, and FIG. 41(b) shows a case where the T/S was 75 mm. In these figures, the temperatures described was annealing temperatures (500° C. or 600° C.).

The results in these figures show that when the distance between target and substrate increases, (004) peaks become larger, which shows that orientation of the samples change.

Further, as shown in the above-mentioned FIG. 34(a), as the substrate temperature decreases, the (004) peak grows, which indicates that the substrate temperature was substantially decreased by expansion of the distance between target and substrate, which caused the above growth of (004) peak.

### Example 38

### Distance between Target and Substrate at a Time of Film-Forming vs. Temperature Dependence of Resistivity, Carrier Density and Hole Mobility

Samples were produced in the same manner as Example 30 except that the distance T/S between target and substrate in the chamber in the sputtering apparatus at times of forming precursor layers, was 50 mm, the O₂/(Ar+O₂) ratio in the sputtering gas was 10 vol % and the annealing temperature was 600° C.

FIG. 42 is a view showing measurement results of electrical characteristics (resistivity, carrier density and mobility) of metal oxide layers of the samples obtained at different measurement temperatures within the range of 10 to 300 K. In FIG. 42, (A) shows a case where the distance T/S between target and substrate was 50 mm, and (B) shows a case where the T/S was 75 mm. Further, (a) shows resistivity, (b) shows carrier density and (c) shows hole mobility that are measurement results.

As compared with FIG. 42(A), in FIG. 42(B), hole mobility significantly increases and the resistivity slightly decreases. Further, it is understandable from these results and the results of the above-mentioned FIG. 41 that as the distance between target and substrate increased, the (004) peak grew and the mobility increased. Further, the resistivity decreases according to orientation of crystal axis.

Regarding Interpretation of Right

In the above, the present invention has been described with reference to specific embodiments. However, it is a matter of course that a person skilled in the art can modify or substitute these embodiments within a range not deviating from the gist of the present invention. Namely, the present invention has been disclosed in a form of exemplification, and the present invention should not be interpreted as limited to the description of the present invention. The gist of the present invention should be understood by taking the Claims into consideration.

Further, it is apparent that the embodiments for describing the present invention can achieve the above-mentioned objects, but it is also understandable that many modifications or other Examples can be carried out by a person skilled in the art. Elements or components of claims, the specification, drawings and embodiments for explanation, may be combined with another one of these for use. Claims are intended to include these modification or other embodiments into their scopes, and these are included in the technical concept and technical scope of the present invention.

The entire disclosures of Japanese Patent Application No. 2006-077689 filed on Mar. 20, 2006, Japanese Patent Application No. 2006-230821 filed on Aug. 28, 2006 and Japanese Patent Application No. 2007-059077 filed on Mar. 8, 2007 including specifications, claims, drawings and summaries are incorporated herein by reference in their entireties.

What is claimed is:

1. A process for producing electric conductor comprising a step of forming on a surface of a substrate body a precursor layer made of titanium oxide doped with one or at least two dopants selected from the group consisting of Nb, Ta, Mo, As, Sb, Al, Hf, Si, Ge, Zr, W, Co, Fe, Cr, Sn, Ni, V, Mn, Tc, Re, P and Bi; and a step of annealing the precursor layer in a reducing atmosphere to form a metal oxide layer.

2. The process for producing an electric conductor according to claim 1, wherein at least a part of the surface of the substrate body is amorphous.

3. The process for producing an electric conductor according to claim 2, wherein at least a part of the is surface of the substrate body is a glass.

4. The process for producing an electric conductor according to any one of claims 1 to 3, wherein the dopant is Nb.

5. The process for producing an electric conductor according to any one of claims 1 to 4, wherein the temperature of the substrate body at a time of forming the precursor layer is at most 600° C.

6. The process for producing an electric conductor according to any one of claims 1 to 5, wherein the precursor layer is formed by a pulse laser deposition method or a sputtering method.

7. The process for producing an electric conductor according to claim 6, wherein the precursor layer is formed in a state that the substrate body is not heated.

8. The process for producing an electric conductor according to any one of claims 1 to 7, wherein the temperature of the substrate body at a time of annealing the precursor layer is at least 300° C. and at most 900° C.

9. The process for producing an electric conductor according to any one of claims 1 to 8, wherein the thickness of the metal oxide layer is from 20 to 1,000 nm.
